(19) United States
(12) Patent Application Publication
(10) Pub. No.: US 2023/0049782 A1
(43) Pub. Date: Feb. 16, 2023

(54) ANISOTROPIC THERMAL CONDUCTORS

(71) Applicant: The University of Chicago, Chicago, IL (US)

(72) Inventors: Jiwoong Park, Chicago, IL (US); Shi En Kim, Chicago, IL (US); Fauzia Mujid, Chicago, IL (US); Joonki Suh, Ulsan (KR)

(73) Assignee: The University of Chicago, Chicago, IL (US)

(21) Appl. No.: 17/884,115

(22) Filed: Aug. 9, 2022

Related U.S. Application Data
(60) Provisional application No. 63/233,477, filed on Aug. 16, 2021.
(60) Provisional application No. 63/231,445, filed on Aug. 10, 2021.

(51) Int. Cl. H01L 23/373

(52) U.S. Cl. CPC H01L 23/3735; H01L 23/3736

(57) ABSTRACT

Articles, devices, and methods including anisotropic van der Waals thermal conductors are described.

### RELATED APPLICATIONS

This application claims priority under 35 U.S.C. § 119(e) to U.S. Provisional Pat. Application No. 63/233,477, filed Aug. 16, 2021, and entitled “Anisotropic Thermal Conductors,” and to U.S. Provisional Pat. Application No. 63/231,445, filed Aug. 10, 2021, and entitled “Extremely Anisotropic Van Der Waals Thermal Conductors,” each of which is incorporated herein by reference in its entirety for all purposes.

### GOVERNMENT SPONSORSHIP

This invention was made with Government support under grants FA9550-18-1-0480 and FA9550-16-1-0031, awarded by the United States Air Force Office of Scientific Research and grant 2011854, awarded by the National Science Foundation. The Government has certain rights in the invention.

### TECHNICAL FIELD

Anisotropic thermal conductors are generally described.

### BACKGROUND

The densification of integrated circuits and the ever-increasing power densities supplied to modern portable devices make it desirable to develop thermal management strategies and high thermal conductivity materials to keep pace with the trend of miniaturization in electronics. Current heat management materials are often insufficient to meet thermal management needs in modern electronics. Accordingly, improved articles and devices are needed.

### SUMMARY

Anisotropic thermal conductors are generally described. Some embodiments are related to multi-layer anisotropic thermal conductors in which the layers interact with each other via Van der Waals forces. The subject matter of the present disclosure involves, in some cases, interrelated products, alternative solutions to a particular problem, and/or a plurality of different uses of one or more systems and/or articles.

In one aspect, devices are provided. In some embodiments, the device comprises a heat source; a substrate; and a multi-layer domain between the heat source and the substrate, the multi-layer domain having a first thermal conductivity in a lateral dimension and a second thermal conductivity in a thickness dimension; wherein the first thermal conductivity is at least 10 times greater than the second thermal conductivity.

In one aspect, articles are provided. In certain embodiments, the article comprises a multi-layer domain between the heat source and the substrate, the multi-layer domain having a first thermal conductivity in a lateral dimension and a second thermal conductivity in a thickness dimension; wherein the first thermal conductivity is at least 10 times greater than the second thermal conductivity.

Other advantages and novel features of the present disclosure will become apparent from the following detailed description of various non-limiting embodiments of the invention when considered in conjunction with the accompanying figures. In cases where the present specification and a document incorporated by reference include conflicting and/or inconsistent disclosure, the present specification shall control.

### BRIEF DESCRIPTION OF THE DRAWINGS

Non-limiting embodiments of the present invention will be described by way of example with reference to the accompanying figures, which are schematic and are not intended to be drawn to scale. In the figures, each identical or nearly identical component illustrated is typically represented by a single numeral. For purposes of clarity, not every component is labeled in every figure, nor is every component of each embodiment of the invention shown where illustration is not necessary to allow those of ordinary skill in the art to understand the invention. In the figures:

FIG. 1A is a schematic side view of a multi-layer domain, according to some embodiments;

FIG. 1B is a schematic top view of a multi-layer domain showing a staggered configuration for each of the layers within the multi-layer domain, according to some embodiments;

FIG. 2 is a cross-sectional schematic diagram of a device comprising a heat source, a substrate, and a multi-layer domain between the heat source and the substrate that anisotropically conducts thermal energy parallel to the surface of substrate, according to some embodiments;

FIG. 3 illustrates a conceptual strategy for engineering thermal anisotropy in a single material system where a random interlayer rotation in polycrystalline vdW layered materials is used, according to some embodiments;

FIG. 4A shows a schematic of an r-MoS₂ film with random crystalline orientation, according to some embodiments;

FIG. 4B shows TEM electron diffraction patterns probed from a 500 nm x 500 nm area of a monolayer and a N = 10 of r-MoS₂ films and an inset image of a Dark-field TEM image of a monolayer with a scale bar denoting 400 nm and also showing different domain orientations from different crystal domains, according to one set of embodiments;

FIG. 4C shows a HAADF-STEM image of a cross-section of a N =10 r-MoS₂ film on AlOₓ coated with Al, with an interlayer spacing of 6.4 Å, according to some embodiments;

FIG. 4D shows large-area MoS₂ films transferred onto 1-inch diameter fused silica substrates, according to some embodiments;

FIGS. 5A-5E show through-plane thermal properties of r-MoS₂, according to some embodiments; FIG. 5A shows TDTR heat dissipation curves of N-layer r-MoS₂ films and an inset schematic of a TDTR sample geometry, according to some embodiments; FIG. 5B shows measured thermal resistances across r-TMD films in which the thermal conductivities for r-MoS₂ and r-WS₂ are calculated from the slope using the formula R_{TDTR} = R₀ + Nd/κ⊥ in which R₀ is the total interfacial thermal resistance, according to some embodiments; FIG. 5C shows experiment and MD simulation results of κ(T) of MoS₂ and r-MoS₂ films in which dotted lines connecting the individual data points are guides to the eye, according to some embodiments; FIG. 5D shows LA (top) and TA (bottom) phonon dispersion curves of r-MoS₂ along the Γ-A direction in which dotted lines denote acoustic curves corresponding to bulk MoS₂, according to some embodiments; and FIG. 5E shows a lifetime of LA and TA phonons parallel to a Γ-A direction in bulk and r-MoS₂, where a dashed line corresponds to the LA mode vibration period derived from the dispersion curve in FIG. 5D, according to some embodiments;

FIGS. 6A-6D show in-plane thermal properties and thermal anisotropy of r-MoS₂ films, according to some embodiments; FIG. 6A shows a 45° SEM micrograph of a N = 4 r-MoS₂ film suspended on a TEM grid for Raman thermometry, according to some embodiments; FIG. 6B shows Raman spectra of a N = 2 r-MoS₂ film with different absorbed laser powers and an inset schematic of a Raman thermometry sample geometry, according to some embodiments; FIG. 6C shows A_{1g} Raman peak shifts vs power absorbed by r-MoS₂ films of various N and an inset schematic of layer-dependent thermal conductance values (absorbed power divided by temperature increase) in domain size D = 1 µm and D = 400 nm r-MoS₂ films, according to some embodiments; and FIG. 6D shows a comparison of p (y-axis), κₛ (x-axis), and κ_{f} (diagonal dashed lines) measured for different anisotropic thermal conductors where r-MoS₂ has an ultrahigh p close to 900, which is larger than bulk MoS₂, pyrolytic graphite (PG), and disordered layered WSe₂, according to some embodiments;

FIG. 7A shows a schematic of the sample configuration of r-MoS₂ draped across a current-carrying Au electrode that is 100 nm wide, 15 nm thick, and 10 µm long, according to some embodiments;

FIG. 7B shows a thermal finite element modeling results of Au electrodes (bare, covered with 10 nm-thick r-MoS₂) at constant heating power of 8 mW supplied through Joule heating, according to some embodiments;

FIG. 7C shows lateral profiles of temperature increases across a Au/SiO₂ surface (solid dots) and on a r-MoS₂ top surface (open circles) and an inset image of cross-sectional temperature distribution of Au electrodes with and without r-MoS₂, using the same scale as FIG. 7B, according to some embodiments;

FIG. 7D shows I-V curve of an Au electrode, with and without N = 16 r-MoS₂, and an inset image of optical micrographs of six fabricated Au electrodes, according to some embodiments;

FIG. 7E shows a histogram of I_{c} of Au electrodes with and without a N = 16 r-MoS₂ heat spreader and their median values, according to some embodiments;

FIG. 8 shows GIWAXS data of N = 10 r-MoS₂, where the peak position corresponds to a 2-Theta value of 14 °, which translates to an interlayer spacing of 6.4 Å (scattering direction), according to some embodiments;

FIGS. 9A-9C show TDTR array measurements of N = 10 r-MoS₂, according to some embodiments; FIG. 9A shows a microscope image of a N = 10 r-MoS₂ film coated with a square grid of Al pads, according to some embodiments; FIG. 9B shows a 4 × 4 TDTR map of R_{TDTR} of a N = 10 r-MoS₂ film, according to some embodiments; and FIG. 9C shows a histogram of R_{TDTR} array measurements, according to some embodiments;

FIG. 10 shows TDTR measurements of N ≤ 10 r-TMD films coated with Au or Al, according to some embodiments;

FIG. 11 shows picosecond acoustics of a MoS₂ monolayer on thick sapphire substrate, coated with an Al transducer layer, in which the y-axis Vᵢₙ is an in-phase signal of a lock-in amplifier, the red arrows indicate acoustic waves reflected at a Al/MoS₂ interface, and the speed of sound of Al as 6.42 nm ps⁻¹ is used to calculate the thickness of A1 (about 93 nm), in accordance to certain embodiments;

FIGS. 12A-12B show low frequency Raman mode+++s of r-MoS₂, according to some embodiments; FIG. 12A shows Raman spectra reflecting the breathing modes (BM) of r-MoS₂ and a shear mode (SM) for bulk MoS₂, according to some embodiments; and FIG. 12B shows a low frequency Raman peak positions of r-MoS₂ and exfoliated MoS₂, in which filled squares indicate BM peak positions of r-MoS₂, open squares indicate BM peak positions of exfoliated MoS₂, and open circles indicate SM peak positions of exfoliated MoS₂, according to some embodiments;

FIGS. 13A-13C show Raman thermometry on r-MoS₂ films, according to some embodiments; FIG. 13A shows Δω-P_{abs} curves of representative N = 2 r-MoS₂ films at different pressures, in which P_{abs} values along the x-axis are normalized to account for slight differences in beam spot sizes (Δr = 20%), according to some embodiments; FIG. 13B shows optical absorption of suspended r-MoS₂ films, which follows the trend A = 1 - (1 - A₀)^{N}, whereby A₀ comprises a monolayer absorptance, which was determined from the fit as A₀ = 0.08 ± 0.003, according to some embodiments; and FIG. 13C shows A_{1g} peak shifts vs power absorbed by r-MoS₂ films made up of D = 400 nm (grain size) monolayers, according to some embodiments;

FIGS. 14A-14B show temperature coefficients of r-MoS₂ for Raman thermometry, according to some embodiments; FIG. 14A shows ω-T calibration measurements of suspended r-MoS₂ films (D = 1 µm), with N = 2 and N = 4 data as representative curves, according to some embodiments; and FIG. 14B shows ω-T slopes vs layer number for all films, according to some embodiments;

FIG. 15 shows κ(T) of r-MoS₂, with κ∥ measured using Raman thermometry of N = 4 r-MoS₂, and κ⊥ measured via TDTR as reported in FIG. 5C, according to some embodiments;

FIG. 16 shows a catalogue of experimentally-measured anisotropy ratios at room temperature vs slow-axis thermal conductivity (κₛ) of thermally anisotropic materials from literature, by category, according to some embodiments;

FIG. 17 shows finite element simulations of the linear temperature profiles of Au electrodes covered with MoS₂ and r-MoS₂, according to some embodiments;

FIG. 18 shows SiNₓ as heat spreaders for Au electrodes, where electrical properties of 10 nm thick, 100 nm wide, and 10 µm long Au electrodes before and after 16 nm SiNₓ film deposition onto the electrodes using plasma-enhanced chemical vapor deposition were measured, according to some embodiments; and

FIGS. 19A-B show optimization of the MD simulations for κ calculations, according to some embodiments; FIG. 19A shows optimization of the driving force of the system, whereby the grey zone denotes the error, according to some embodiments; and FIG. 19B shows an effect of thermal expansion on κ, according to some embodiments.

### DETAILED DESCRIPTION

Anisotropic thermal conductors are described herein. In certain embodiments, the thermal conductors are configured such that the flow of thermal energy is anisotropic (i.e., heat may dissipate relatively quickly in one direction while dissipating slowly in another direction). This can result in an extremely anisotropic thermal conductor where heat quickly dissipates in a lateral direction of the thermal conductor while dissipating slowly a thickness direction of the thermal conductor. The anisotropic thermal conductor may comprise a multi-layer domain comprising at least two thin films, such as two-dimensional (2D) materials. In some embodiments, two or more layers of the domain interact with each other via Van der Waals forces. In some embodiments, each layer of the domain interacts with at least one other layer via Van der Waals forces. In certain embodiments, each layer of the multi-layer domain may be slightly offset or rotated relative to an adjacent layer such that at least some of the layers have a staggered crystallographic orientation relative to adjacent layer(s). It has been discovered within the context of this disclosure that staggering the layers such that at least some of the layers have crystal structures that are unaligned relative to one or more adjacent layers may result efficient heat transfer in the plane of the layer and inefficient heat transfer from layer to layer.

In some embodiments, two or more layers within the multi-layer domain have a high thermal conductivity along their planes and low thermal conductivity from layer-to-layer. This can lead to a multi-layer domain comprising these layers having a high thermal conductivity along its width and depth (e.g., due to high thermal conductivity along the planes of the layers) and a low thermal conductivity through its thickness (e.g., due to low layer-to-layer thermal conductivity within the multi-layer domain). In some such embodiments, heat conduction along or parallel to the plane of the layers is relatively high, while heat conduction perpendicular to the layers is relatively low, such that the multi-layer domain behaves as an extremely anisotropic thermal conductor.

The layer(s) within the multi-layer domain may be, in certain embodiments, single crystalline or polycrystalline. Without wishing to be bound by any particular theory, it is believed that in domains comprising multiple crystalline layers (e.g., single crystalline or polycrystalline layers), phonons efficiently travel in the planar dimensions of each crystalline layer (i.e., parallel to the faces of the layers) but travel poorly from layer to layer (i.e., perpendicular to the faces of the layers) due to lack of long-range order across the thickness of the multi-layer domain. This can be a result of rotational staggering within the crystal lattices of the adjacent layers. In cases where single crystalline layers are used, such staggering can be achieved by rotating each layer around an axis perpendicular to the face of the layer, relative to the underlying layer. Rotation of layers is not strictly required, however, and in some embodiments the staggering of adjacent lattices can be achieved in other ways. For example, such staggering can be achieved in multi-layer domains in which polycrystalline materials are used, for example, by ensuring that the orientation of the crystal lattices within each polycrystalline layer are sufficiently diverse such that the orientations of the crystal lattices within each layer do not match the orientations of the crystal lattices within adjacent layer(s). In some embodiments, the grain boundaries within one polycrystalline layer may create enough misalignment with the grains of a different, adjacent polycrystalline layer, such that phonon transport is more efficient in plane of the layers and less efficient through the plane of the polycrystalline layers. That is to say, the polycrystalline layers may be less disordered from grain to grain within the layer while more disordered through the thickness of the polycrystalline layers of the multi-layer domain.

It is believed that such misalignment of the crystal lattices within adjacent layers of the multi-layer domain renders phonon transport through the thickness of the multi-layer domain (i.e., from layer-to-layer) less efficient, while phonon transport within each layer and parallel to the layers is more efficient, resulting in an anisotropic thermal conductor.

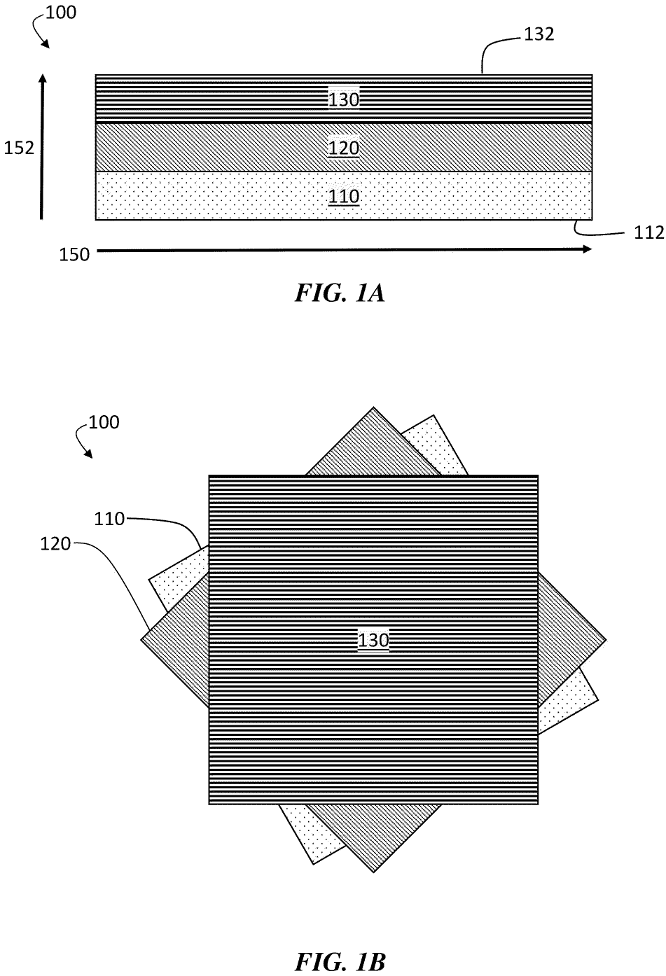

Various embodiments described herein include a multi-layer domain. The multi-layer domain may comprise a plurality of layers stacked or arranged adjacent to one another. For example, FIG. 1A schematically depicts a side view of a multi-layer domain comprising a plurality of layers. In FIG. 1A, multi-layer domain 100 comprises first layer 110, second layer 120, and third layer 130, each adjacent to one another. First layer 110 is also the bottom most layer of the multi-layer domain 100 and features a bottom-most surface 112, while third layer 130 is the topmost layer and features topmost surface 132. Meanwhile, second layer 120 is between the first layer 110 and the third layer 130 and is an intervening layer relative to first layer 110 and third layer 130.

It should be understood that when a portion (e.g., layer, structure, region) is “on”, “adjacent”, “above”, “over”, “overlying”, or “supported by” another portion, it can be directly on the portion, or an intervening portion (e.g., layer, structure, region) may also be present. Similarly, when a portion is “below” or “underneath” another portion, it can be directly below the portion, or an intervening portion (e.g., layer, structure, region) may also be present. A portion that is “directly adjacent”, “directly on”, “immediately adjacent”, “in contact with”, or “directly supported by” another portion means that no intervening portion is present. It should also be understood that when a portion is referred to as being “on”, “above”, “adjacent”, “over”, “overlying”, “in contact with”, “below”, or “supported by” another portion, it may cover the entire portion or a part of the portion.

It should also be understood that while the multi-layer domain shown in FIG. 1A has three layers, the plurality of layers of the multi-layer domain may have any suitable number of layers. In some embodiments, the multi-layer domain includes at least 2 layers, at least 3 layers, at least 5 layers, at least 7 layers, at least 10 layers, at least 15 layers, at least 20 layers, at least 25 layers, at least 50 layers, at least 75 layers, at least 100 layers, at least 250 layers, at least 500 layers, or at least 1000 layers. In some embodiments, the multi-layer domain includes no greater than 1000 layers, no greater than 500 layers, no greater than 250 layers, no greater than 100 layers, no greater than 75 layers, no greater than 50 layers, no greater than 25 layers, no greater than 20 layers, no greater than 15 layers, or no greater than 10 layers. Combinations of the foregoing ranges are also contemplated (e.g., at least 2 layers and no greater than 500 layers). Other ranges are also possible.

FIG. 1B, schematically depicts rotation or staggering of the adjacent layers, which can be employed in certain but not necessarily all embodiments. In FIG. 1B, a schematic top view of multi-layer domain 100 is shown, where the topmost layer, third layer 130, faces the viewer, with topmost surface 132 completely exposed. Second layer 120 is directly beneath third layer 130 and rotated relative to third layer 130, while first layer 110 is directly beneath second layer 120 and is rotated relative to both second layer 120 and third layer 130. In such a configuration, when single-crystalline materials are employed, the orientation of the crystal lattice within each layer of the multi-layer domain 100 is staggered relative to an adjacent layer. As explained in more detail elsewhere herein, staggering the layers of the multi-layer domain in this manner may result in lower thermal conduction along a thickness of the multi-layer domain (e.g., in to and out of the plane of the page of FIG. 1B) and higher thermal conduction along a lateral dimension of the multi-layer domain (e.g., parallel to the surface of the plane of the page of FIG. 1B).

In some embodiments, at least one layer of the multi-layer domain is arranged such that the crystallographic orientation of that layer is rotated, around an axis that is perpendicular to the surface of that layer of the multi-layer domain, by at least 0.1° (or at least 0.5°, at least 1°, at least 2°, at least 3°, at least 4°, at least 5°, at least 10°, at least 15°, at least 20°, at least 25°, at least 30°, or more) relative to the crystallographic orientation of a second layer immediately adjacent to that layer. For example, in FIGS. 1A-1B, layers 110 and 120 are arranged such that the crystallographic orientation of layer 120 is rotated by several degrees relative to the crystallographic orientation of layer 110. In some such embodiments, the layer and the second layer are made of the same material. In some such embodiments, the layer and the second layer are both single crystalline layers. In some embodiments, at least two, at least three, at least four, at least five, at least six, at least seven, at least eight, at least nine, at least ten, at least 12, at least 15, at least 20, or more layers of the multi-layer domain are arranged as described in this paragraph.

In certain embodiments, at least one layer of the multi-layer domain is arranged such that across at least 10% (or across at least 20%, at least 30%, at least 40%, at least 50%, at least 75%, at least 90%, at least 95%, at least 99%, or more) of the facial area of the layer, the crystallographic orientation of that layer is rotated, around an axis that is perpendicular to the surface of that layer of the multi-layer domain, by at least 0.1° (or at least 0.5°, at least 1°, at least 2°, at least 3°, at least 4°, at least 5°, at least 10°, at least 15°, at least 20°, at least 25°, at least 30°, or more) relative to the crystallographic orientation of the corresponding portion of a second layer immediately adjacent to that layer. In some such embodiments, the layer and the second layer are made of the same material. In some such embodiments, the layer and the second layer are both polycrystalline layers. In some embodiments, at least two, at least three, at least four, at least five, at least six, at least seven, at least eight, at least nine, at least ten, at least 12, at least 15, at least 20, or more layers of the multi-layer domain are arranged as described in this paragraph.

While FIG. 1B schematically depicts all of the layers of the multi-layer domain in a staggered configuration, it should be understood that, for some embodiments, only some (or none) of the layers may be staggered. For example, in a multi-layer domain comprising 5 layers, two of the layers could be aligned, while another two of the layers could be staggered relative to the first two layers, while the remaining layer could be rotated such that it aligns with the first two layers, but not the second two layers.

In certain embodiments, none of the layers are staggered or rotated relative to one another, such that all of the layers are aligned with one another. In certain of embodiments, thermal conduction perpendicular to the layers may still be lower than thermal conduction in plane or parallel to the layers due to properties of the layers (e.g., crystallinity of one or more layers within the multi-layer domain). Those skilled in the art in view of the present disclosure will be capable of selecting an arrangement of layer rotations, staggerings, and alignments, for example, to tune or modify the thermal conductivity in a thickness direction of the multi-layer domain.

In some embodiments, the multi-layer domain (and/or a layer within the multi-layer domain) has a first thermal conductivity in a lateral dimension and a second thermal conductivity in a thickness dimension. The term “lateral dimension” is used herein to refer to dimensions of the multi-layer domain that are parallel to the faces of the layers that make up the multi-layer domain (such as dimension 150 in FIG. 1A), and the term “thickness dimension” is used to refer to the dimensions of the multi-layer domain that are perpendicular to the faces of the layers that make up the multi-layer domain (such as dimension 152 in FIG. 1A). When the thermal conductivities of the multi-layer domain are different in a lateral dimension than in a thickness dimension, this may result in anisotropic thermal conductivity of the multi-layer domain.

The thermal conductivity of the multi-layer domain (or a layer within the multi-layer domain) can be measured using time domain thermoreflectance (TDTR).

In some embodiments, the thermal conductivity of the multi-layer domain in a lateral dimension is greater than the thermal conductivity of the multi-layer domain in a thickness dimension. In some embodiments, the thermal conductivity of the multi-layer domain in a lateral dimension is at least 10 times, at least 50 times, at least 100 times, at least 500 times, at least 750 times, or at least 900 times greater than the thermal conductivity of the multi-layer domain in a thickness dimension. In some embodiments, the thermal conductivity of the multi-layer domain in a lateral dimension is less than or equal to 1×10¹⁵ times, less than or equal to 1×10¹² times, less than or equal to 1×10⁹ times, less than or equal to 1,000,000 times, less than or equal to 100,000 times, less than or equal to 10,000 times, or less than or equal to 1,000 times greater than the thermal conductivity of the multi-layer domain in a thickness dimension.

In some embodiments, the thermal conductivity anisotropy of the multi-layer domain (or a layer within the multi-layer domain) can be expressed as a ratio (ρ) between the thermal conductivities along the fast axis (κ_{F}) and the slow axis (κ_{S}), or ρ = (κ_{F}/κ_{S}). In some embodiments, this may be expressed as a ratio of the thermal conductivity in a lateral dimension to the thermal conductivity in a thickness dimension. In some embodiments, ρ can be at least 10, at least 50, at least 100, at least 500, at least 750, or at least 900. In some embodiments, ρ can be less than or equal to 1×10¹⁵, less than or equal to 1×10¹², less than or equal to 1×10⁹, less than or equal to 1,000,000, less than or equal to 100,000, less than or equal to 10,000, or less than or equal to 1,000. Combinations of these ranges are also possible (e.g., at least 10 and less than or equal to 1×10¹⁵). Other ranges are also possible.

In some embodiments, the thermal conductivity of the multi-layer domain (and/or a layer within the multi-layer domain) in a lateral dimension is greater than or equal to 35 W m⁻¹ K⁻¹, greater than or equal to 50 W m⁻¹ K⁻¹, greater than or equal to 100 W m⁻¹ K⁻¹, greater than or equal to 500 W m⁻¹ K⁻¹, greater than or equal to 1000 W m⁻¹ K⁻¹, greater than or equal to 2500 W m⁻¹ K⁻¹, or greater than or equal to 4000 W m⁻¹ K⁻¹ at 25° C. In some embodiments, the first thermal conductivity of the multi-layer domain is less than or equal to 1,000,000 W m⁻¹ K⁻¹, less than or equal to 100,000 W m⁻¹ K⁻¹, or less than or equal to 10,000 W m⁻¹ K⁻¹ at 25° C. Combinations of the above-referenced ranges are also possible (e.g., greater than or equal to 35 W m⁻¹ K⁻¹ and less than or equal to 1,000,000 W m⁻¹ K⁻¹). Other ranges are possible.

In certain embodiments, the thermal conductivity of the multi-layer domain (and/or a layer within the multi-layer domain) in a thickness dimension is less than or equal to 1 W m⁻¹ K⁻¹, less than or equal to 500 mW m⁻¹ K⁻¹, less than or equal to 200 mW m⁻¹ K⁻¹, less than or equal to 150 mW m⁻¹ K⁻¹, less than or equal to 100 mW m⁻¹ K⁻¹, less than or equal to 75 mW m⁻¹ K⁻¹, less than or equal to 50 mW m⁻¹ K⁻¹, less than or equal to 25 mW m⁻¹ K⁻¹, less than or equal to 10 mW m⁻¹ K⁻¹, less than or equal to 1 mW m⁻¹ K⁻¹, or less than or equal to 0.1 mW m⁻¹ K⁻¹ at 25° C. In some embodiments, the second thermal conductivity is greater than or equal to 0.1 mW m⁻¹ K⁻¹, greater than or equal to 1 mW m⁻¹ K⁻¹, greater than or equal to 10 mW m⁻¹ K⁻¹, or greater than or equal to 25 mW m⁻¹ K⁻¹ at 25° C. Combinations of the above-referenced ranges are also possible (e.g., less than 1 W m⁻¹ K⁻¹ and greater than 0.1 mW m⁻¹ K⁻¹). Other ranges are also possible.

As mentioned above, the multi-layer domain may comprise a plurality of layers. In some embodiments, a layer is a crystalline layer, such as a single-crystalline layer or a polycrystalline layer. In some embodiments, the multi-layer domain comprises at least one (or at least two, at least three, at least five, at least ten, or more) single crystalline layer. In some embodiments, the multi-layer domain comprises at least one (or at least two, at least three, at least five, at least ten, or more) polycrystalline layer. In some embodiments, each layer of the multi-layer domain may independently have the same or different composition than another layer of the multi-layer domain. In some embodiments, the multi-layer domain comprises a plurality of layers of the same chemical composition

In some embodiments, one or more layers of the multi-layer domain is a thin film layer. In some embodiments, the multi-layer domain comprises at least two thin film layers. A thin film is a film having a thickness of less than or equal to 1 micrometer. The thickness of a film is determined as the average thickness of the film, determined as a number average and measured across the entirety of its surface. In some embodiments, the thickness of the thin film layer(s) within the multi-layer domain is less than or equal to 900 nanometers, less than or equal to 800 nanometers, less than or equal to 700 nanometers, less than or equal to 600 nanometers, less than or equal to 500 nanometers, less than or equal to 250 nanometers, or less than or equal to 100 nanometers. In some embodiments, the thickness of the thin film layer(s) of the multi-layer domain is greater than or equal to 0.5 nanometers, greater than or equal to 1 nanometer, or greater than or equal to 10 nanometers. Combinations of the foregoing ranges are also possible (e.g., greater than or equal to 0.5 nanometers and less than or equal to 1 micrometer). Other ranges are also possible.

In some embodiments, one or more layers of the multi-layer domain comprises a two-dimensional (2D) material (e.g., the multi-layer domain comprises at least two two-dimensional material layers). Non-limiting examples of 2D materials include graphene, hexagonal boron nitride (hBN), BP, MoS₂, MoSe₂, WS₂, WSe₂, TiS₃, SnS, SnS₂, InSe, In₂Se₃, GaSe, GaTe, ReS₂, ReSe₂, NbSe₂, and TaS₂. In some embodiments, one or more layers of the multi-layer domain comprises a transition metal dichalcogenide (TMDC), such as MoS₂, MoSe₂, MoTe₂, WS₂, and/or WSe₂, without limitation. In some embodiments, one or more layers of the multi-layer domain comprises a van der Waals material (vdW), such as graphene. In some embodiments, the multi-layer domain comprises a layer comprising a transition metal dichalcogenide, graphene, or hexagonal boronitride.

In some embodiments, the variation of the thickness of the layers within the multi-layer domain, across the lateral dimensions of the layers, can be very small. The variation of the thickness of a layer (T_{Var}) is expressed as a percentage and is determined as follows:

$${T}_{V a r} = \frac{\overline{M a {x}_{10}} - \overline{T}}{\overline{T}} \times 100 \%$$

where Max₁₀ is the number averaged thickness of the ten thickest local maxima of the layer thickness and T̅ is the average thickness of the layer. In some embodiments, the variation in the thickness of the layer is less than 10%, less than 5%, less than 2%, or less than 1%.

In some embodiments, one or more (or all) of the layers within the multi-layer domain are continuous. A layer is considered to be continuous when it has fewer than 10⁷ through-thickness defects having cross-sectional areas of greater than 1 square micrometer per cm² of the facial area of the layer. The cross-sectional area of a defect is measured in a direction perpendicular to the thickness of the layer. In some embodiments, the layer(s) described herein have fewer than 10⁵, fewer than 10³, or fewer than 10 defects having cross-sectional areas of greater than 1 square micrometer per cm² of the facial area of the layer. In some embodiments, at least two, at least three, at least four, at least five, at least six, at least seven, at least eight, at least nine, at least ten, at least 12, at least 15, at least 20, or more layers of the multi-layer domain are configured as described in this paragraph.

In certain embodiments, the layer(s) and/or the multi-layer domain can have a relatively large minimum lateral dimension. The lateral dimensions of a layer are its dimensions that are perpendicular to its thickness. To illustrate, layer 110 in FIG. 1A has a lateral dimension 150 (as well as another lateral dimension that extends into and out of the page), which is perpendicular to its thickness (which runs in the direction of arrow 152). For a layer with a circular facial area, the minimum lateral dimension would be its diameter. For a layer with an elliptical facial area, the minimum lateral dimension would be its minor axis. In some embodiments, the layer(s) and/or the multi-layer domain has a minimum lateral dimension of at least 10 micrometers, at least 50 micrometers, at least 100 micrometers, at least 500 micrometers, at least 1 centimeter, 5 centimeters, at least 25 centimeters, or at least 50 centimeters (and/or, in some embodiments, up to 100 centimeters, up to 1000 centimeters, up to 100 meters, or more). In some embodiments, at least two, at least three, at least four, at least five, at least six, at least seven, at least eight, at least nine, at least ten, at least 12, at least 15, at least 20, or more layers of the multi-layer domain have the properties described in this paragraph.

In some embodiments, one or more of the layers within the multi-layer domain is freestanding prior to assembly in the multi-layer domain. A freestanding layer is a layer that is not bound to another solid material (such as an adjacent substrate). In some embodiments, at least two, at least three, at least four, at least five, at least six, at least seven, at least eight, at least nine, at least ten, at least 12, at least 15, at least 20, or more layers of the multi-layer domain are freestanding prior to assembly in the multi-layer domain.

In some embodiments, one or more of the layers within the multi-layer domain is self-supporting prior to assembly in the multi-layer domain. A layer is generally considered to be self-supporting when the layer does not dissociate into multiple pieces when it is freestanding and it suspended from one end under the force of gravity. To test whether a layer is self-supporting, one would secure the layer by one of its ends (e.g., using tweezers or using any other suitable method), lift the layer such that it is hanging by its secured end under the force of gravity, and determine whether the layer dissociates into multiple pieces after it has been lifted. A cohesive thin film that can be handled without breaking into multiple pieces under the force of gravity is an example of a layer that is self-supporting. A layer of loosely-bound monomeric material that cannot be handled without dissociating into individuated pieces is an example of a material that is not self-supporting. In some embodiments, the layer can be transferred from one substrate to another substrate without dissociating into multiple pieces. In some embodiments, at least two, at least three, at least four, at least five, at least six, at least seven, at least eight, at least nine, at least ten, at least 12, at least 15, at least 20, or more layers of the multi-layer domain are self-supporting prior to assembly in the multi-layer domain.

The layers of the multi-layer domain may be fabricated using a variety of techniques. In an exemplary embodiment, the layers of the multi-layer domain may be fabricated at the interface of two immiscible liquids, which is described in more detail in International Patent Application No. PCT/US2020/054378, filed on Oct. 6, 2020, and published on Apr. 15, 2021, as International Publication No. WO 2021/071824, which is incorporated herein by reference in its entirety for all purposes. Non-limiting examples of other suitable techniques include atomic layer deposition techniques, molecular beam epitaxy techniques, and/or chemical vapor deposition. Other techniques are possible.

The multi-layer domain may be fabricated from its constituent layers using a variety of techniques. In some embodiments, the layers are assembled by using vacuum to stack each layer adjacent to one another.

In some embodiments, the multi-layer domain may comprise a plurality of thin films (e.g., 2D materials), such as at least two, at least three, at least five, at least ten, or more thin films, stacked such that the thin films are in direct contact with each other. In some such embodiments, each of the stacked thin films interacts with adjacent thin film(s) via Van der Waals forces. In some embodiments, at least two, at least three, at least four, at least five, at least six, at least seven, at least eight, at least nine, at least ten, at least 12, at least 15, at least 20, or more layers of the multi-layer domain are thin films. In some embodiments, at least two, at least three, at least four, at least five, at least six, at least seven, at least eight, at least nine, at least ten, at least 12, at least 15, at least 20, or more layers of the multi-layer domain are 2D materials.

The articles and devices described herein may also comprise a heat source away from which the multi-layer domain may conduct heat. In some such embodiments, a substrate may also be present. In some embodiments, the multi-layer domain is configured to reduce heat transfer between the heat source and the substrate. That is to say, in some embodiments, the multi-layer domain directs heat from the heat source away from the substrate.

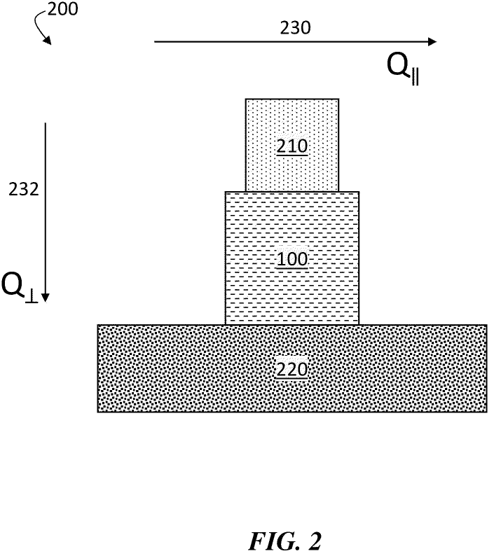

By way of illustration, FIG. 2 schematically depicts the multi-layer domain 100 positioned between heat source 210 and substrate 220. In the figure, multi-layer domain 100 is configured such that the layers of the domain run parallel to the surface of substrate 220. As schematically illustrated in the figure, heat my flow along line 230 and/or line 232, but because of the configuration of multi-layer domain 220, the thermal conductivity along line 230 is greater than the thermal conductivity along line 232. In the configuration shown in FIG. 2, multi-layer domain 100 may reduce heat flow from heat source 210 to substrate 220, while directing most heat along line 230.

The heat source can be any source of heat where it is desired to direct heat generated from the source in one direction but not another direction. In some embodiments, the heat source comprises an electronic circuit element, such as a transistor, a resistor, a capacitor, or an electrode. In some embodiments, the heat source comprises a microprocessor. In some embodiments, the heat source comprises an electrochemical cell or a battery (e.g., a Li-ion battery). In some embodiments, the heat source generates heat due to Joule heating. In some embodiments, the heat source generates heat energy at a rate of at least 1 Watt, at least 10 Watts, at least 100 Watts, at least 1000 Watts, at least 10 kilowatts, at least 100 kilowatts, at least 1 megawatt, or more.

In some embodiments, the device may also include a substrate. The substrate may be a surface of a component within the device, proximate the heat source, where it is desired to reduce or limit heat transfer. In one embodiment, the heat source can be aluminum metal (such as an aluminum metal electrode), the substrate can be aluminum oxide, and the multi-layer domain can be positioned between the aluminum metal and the aluminum oxide such that the layers within the multi-layer domain run parallel to the adjacent surface of the aluminum and the aluminum oxide. Current can be passed through the aluminum metal to generate heat via Joule heating, and the multi-layer domain may dissipate heat in-plane relative to the layers of multi-layer domain, while through-plane heat to the aluminum oxide may be reduced or mitigated compared to the same configuration but absent the multi-layer domain and all other factors remaining equal. In some embodiments, the substrate is a portion of a housing or a case for the device. As another example, the heat source could be a battery within a notebook computer, and the substrate could be the surface of a processor (e.g., a CPU, GPU) within the device, where it is desired to reduce heat transfer between the battery and the processor in order to avoid overheating the processor from heat generated from the battery. In some embodiments, the substrate comprises skin (e.g., human skin or non-human animal skin). Other non-limiting examples of the substrate include semiconductors, metals, polymers, and the like.

In some embodiments, the multi-layer domain is configured to transfer a majority (e.g., at least 50%, at least 75%, at least 90%, at least 95%, at least 99%, or more) of the heat generated by the heat source to a heat sink.

U.S. Provisional Pat. Application No. 63/231,445, filed Aug. 10, 2021, and entitled “Extremely Anisotropic Van der Waals Thermal Conductors” is incorporated herein by references in its entirety for all purposes. U.S. Provisional Pat. Application No. 63/233,477, filed Aug. 16, 2021, and entitled “Anisotropic Thermal Conductors,” is also incorporated herein by reference in its entirety for all purposes. Kim, S.E., Mujid, F., Rai, A. et al. “Extremely anisotropic van der Waals thermal conductors,” Nature, Vol. 597, pages 660-665 (2021) (DOI: https://doi.org/10.1038/s41586-021-03867-8), is also incorporated herein by reference in its entirety for all purposes.

The following example is intended to illustrate certain embodiments of the present invention, but does not exemplify the full scope of the invention.

### EXAMPLE

The densification of integrated circuits and the ever-increasing power densities supplied to modern portable devices make desirable thermal management strategies and high thermal conductivity materials to keep pace with the trend of miniaturization in electronics. Recent innovations include the development of materials with thermal conduction anisotropy, which can not only remove hotspots along the fast-axis direction, but also provide thermal insulation along the slow axis. However, most artificially engineered thermal conductors have anisotropy ratios much smaller than those seen in naturally anisotropic materials. Here, it is reported extremely anisotropic thermal conductors based on large area van der Waals thin films with random interlayer rotations, which produce a room temperature thermal anisotropy ratio close to 900 in MoS₂, one of the highest ever reported. Without wishing to be bound by any particular theory, it is believed that this is aided by the interlayer rotations that impede the through-plane thermal transport, while the long-range intralayer crystallinity maintains high in-plane thermal conductivity.

Using time domain thermoreflectance (TDTR), ultralow thermal conductivities in the through-plane direction were measured for MoS₂ (57 ± 3 mW m⁻¹ K⁻¹) and WS₂ (41 ± 3 mW m⁻¹ K⁻¹) films, and these values were quantitatively rationalized using molecular dynamics simulations that reveal one-dimensional glass-like thermal transport. On the other hand, Raman thermometry measurements show that the in-plane thermal conductivity in these MoS₂ films is close to the single-crystal value, showing that the film retains efficient phonon-mediated thermal transport.

The ultrahigh thermal anisotropy makes these films practically useful as directed heat spreaders for nanoelectronics, which channels heat along one direction but not the other. This has been demonstrated in nanofabricated gold electrodes, where covering them with the anisotropic films described herein creates efficient heat transfer to the underlying substrate preventing overheating of the electrodes, while the excellent through-plane thermal insulation is expected to block heat from reaching the device surface. This work establishes interlayer rotation in crystalline layered materials as a new degree of freedom for engineering directed heat transport in solid-state systems and dense integrated circuitry.

Anisotropic thermal conductors, in which heat flows faster in one direction compared to another, can be characterized by the thermal conductivity anisotropy ratio ρ (ρ = κ_{F}/κ_{S}) between the thermal conductivities along the fast axis (κ_{F}) and the slow axis (κ_{S}). One common way to engineer ρ in fully dense solids is via nanostructuring, such as fabricating inorganic superlattices or designing symmetry-breaking crystal architectures in a single material. However, such engineered materials have relatively small ρ values of less than 20 at room temperature. On the other hand, some natural crystalline materials have an intrinsically large ρ (e.g., graphite, h-BN, with ρ ~ 340 and 90 respectively), but these materials are often difficult to process in a scalable manner for thin film integration. Some of these films may also lack the electrical or optical properties necessary for functional device applications.

To design materials with higher ρ that are also suitable for real-world applications, an approach needs to be developed to include three key features: i) a candidate material with intrinsically high κ_{F}, usually one with efficient phonon-mediated thermal transport; ii) a method to significantly reduce κ_{S} without affecting κ_{F}; and iii) facile, scalable production and integration of such a material with precise control of the material dimensions (e.g., film thickness). Layered van der Waals (vdW) materials such as graphite and transition metal dichalcogenides (TMDs) provide an ideal material platform for designing such high ρ materials. These vdW materials generally have excellent intrinsic in-plane thermal conductivities (κ∥) in single crystalline form. Previous studies have also measured record-low thermal conductivities in turbostratic nanocrystalline vdW films (e.g., WSe₂) and heterostructures. Additionally, layered vdW materials display diverse electronic characteristics (e.g., semiconducting, metallic, and superconducting) and intriguing valley-specific properties that can be harnessed to develop the next generation of electronic and optoelectronic devices, for which thermal management is an important consideration. One currently missing capability, however, is a general and scalable approach for significantly decreasing the out-of-plane thermal conductivity (κ⊥) for κ_{S} while maintaining high κ∥.

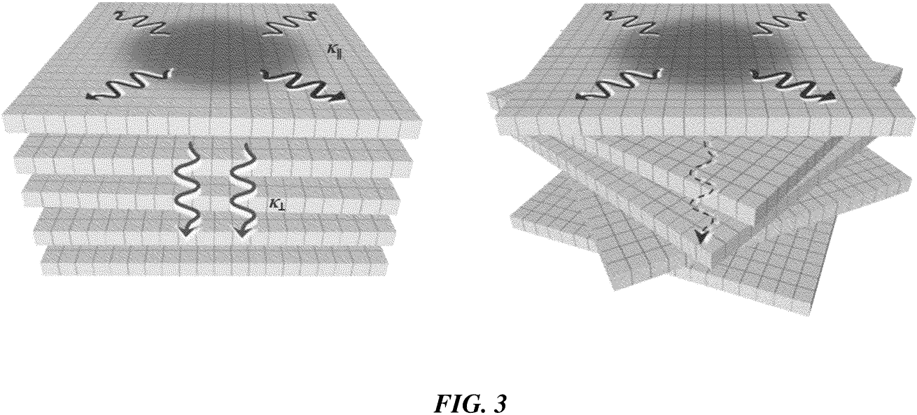

Here, it is shown that such capability is provided by interlayer rotations in vdW materials, as illustrated in FIG. 3. Interlayer rotation breaks the through-plane translational symmetry at the atomic scale while retaining in-plane long-range crystallinity in each monolayer, thereby providing an effective means for suppressing only κ⊥. Large-area TMD films were produced that are composed of polycrystalline monolayers stacked vertically without interlayer registry (referred to here as r-TMD) and independently measure κ⊥ and κ∥. Thermal measurements reveal extremely small κ⊥ values and high κ∥ values in the r-TMD films. As a result, r-MoS₂ has a giant thermal conductivity anisotropy useful for real-world device applications including directed heat transport, which can be realized by integrating the multilayer stack with nanofabricated gold electrodes.

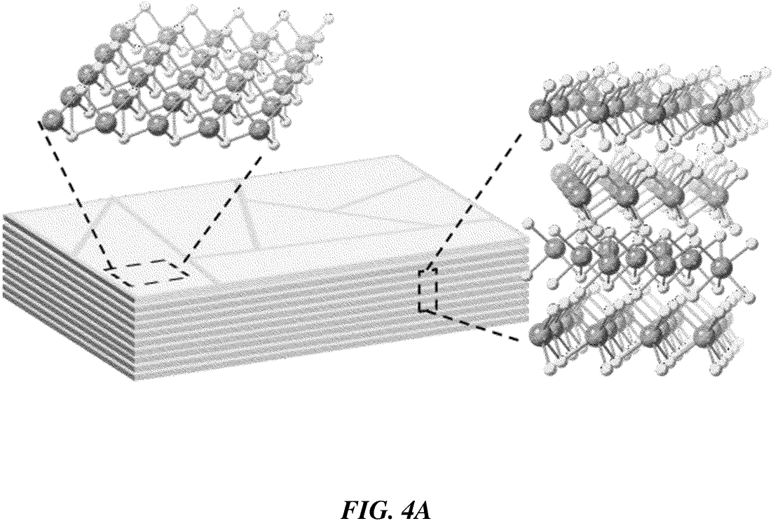

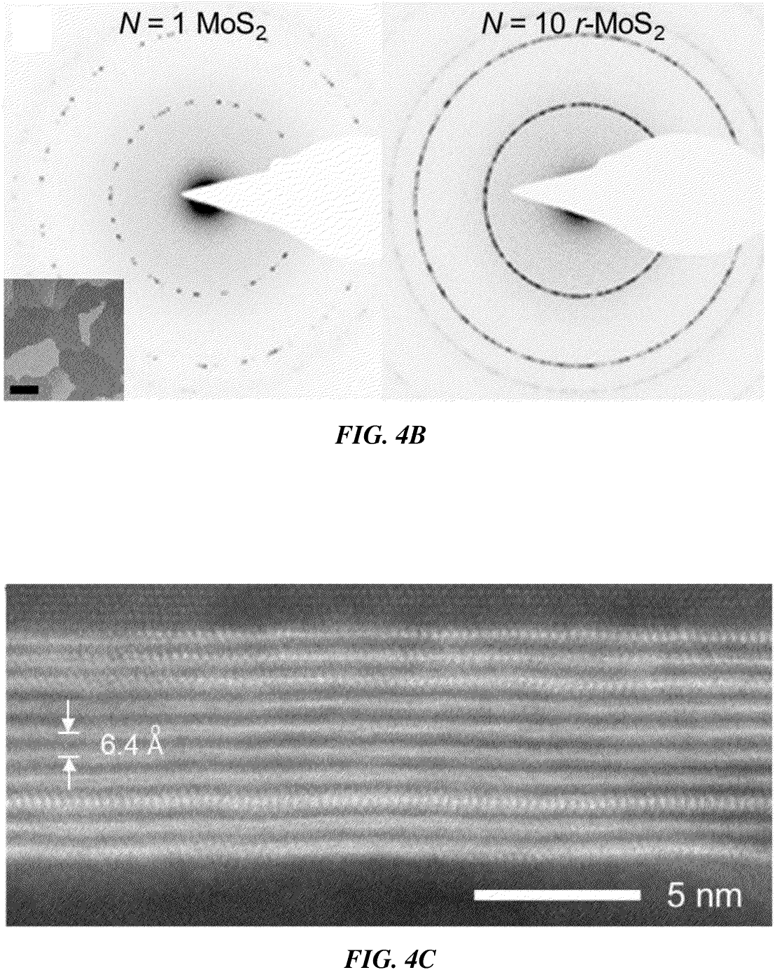

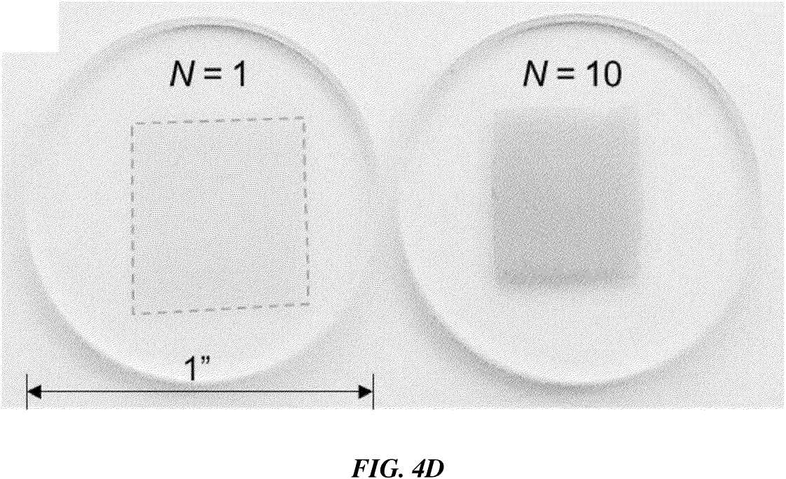

The r-TMD films possess long-range crystallinity in-plane and relative lattice rotations at every interlayer interface (FIG. 4A). To illustrate this, the structural characterization of r-MoS₂ films is shown in FIGS. 4A-4C. The films are produced in large-scale using two steps: monolayer growth and layer-by-layer stacking. In the first step, wafer-scale, continuous TMD monolayers with large crystalline domains (size D) are grown using metal-organic chemical vapor deposition. The transmission electron microscopy (TEM) diffraction (FIG. 4B, left) and darkfield (inset) images from a representative MoS₂ monolayer show that it comprises large (D ≈ 1 µm), randomly-oriented crystalline domains, which connect laterally to form a continuous polycrystalline film. In the second step, these monolayers are stacked one by one under vacuum to generate r-TMD films with a precise layer number (N) and high-quality interfaces, in which the random domain orientations between adjacent monolayers directly lead to interlayer rotation at every stacked interface. Indeed, the TEM diffraction pattern of N = 10 r-MoS₂ (FIG. 4B, right) shows a ring-like pattern due to the significant increase in the number of diffraction spots, emphasizing the random crystalline orientation in the through-plane direction. This vacuum stacking process also produces clean and well-defined interfaces, as can be seen from the cross-sectional high-angle annular dark field scanning TEM (HAADF-STEM) images of r-MoS₂ (FIG. 4C). FIG. 4C shows 10 bright, parallel lines, each corresponding to a continuous MoS₂ monolayer. The monolayers have a uniform interlayer spacing d ≈ 6.4 Å, measured via grazing-incidence wide- angle x-ray scattering (GIWAXS), which is close to the expected value (6.5 Å) for twisted MoS₂ multilayers based on calculations.

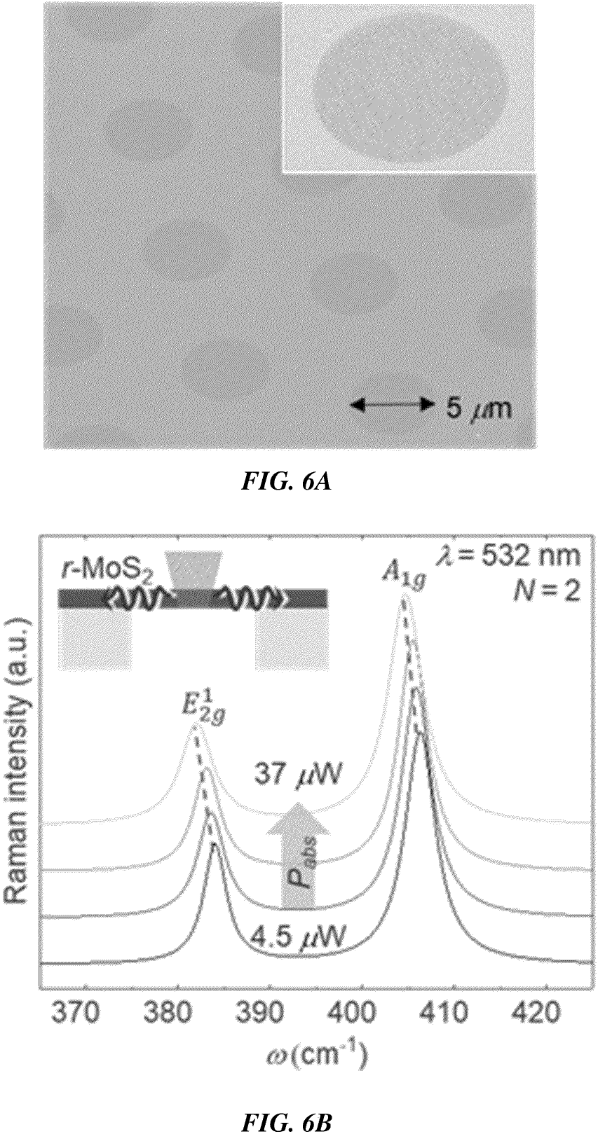

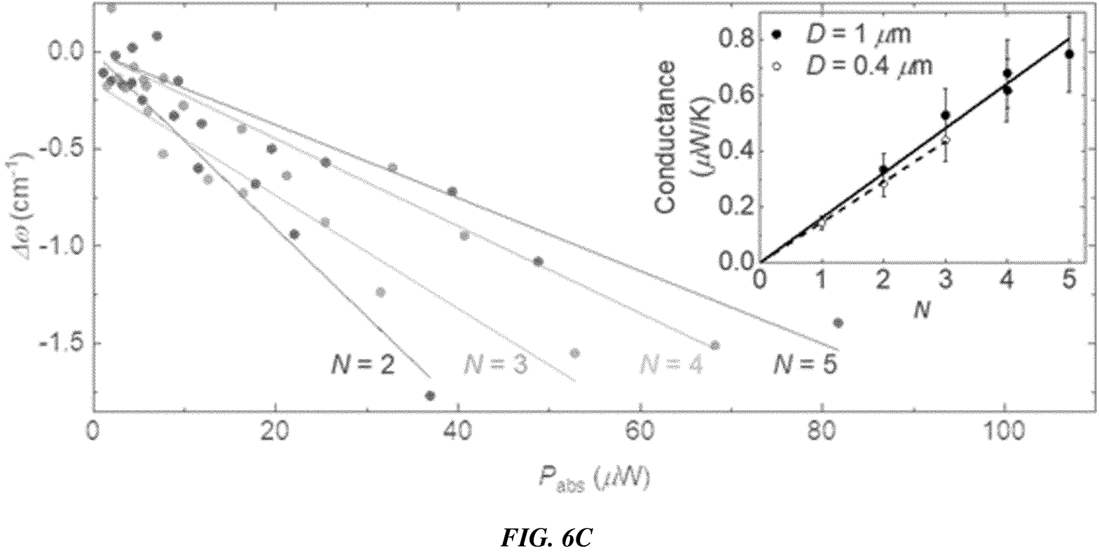

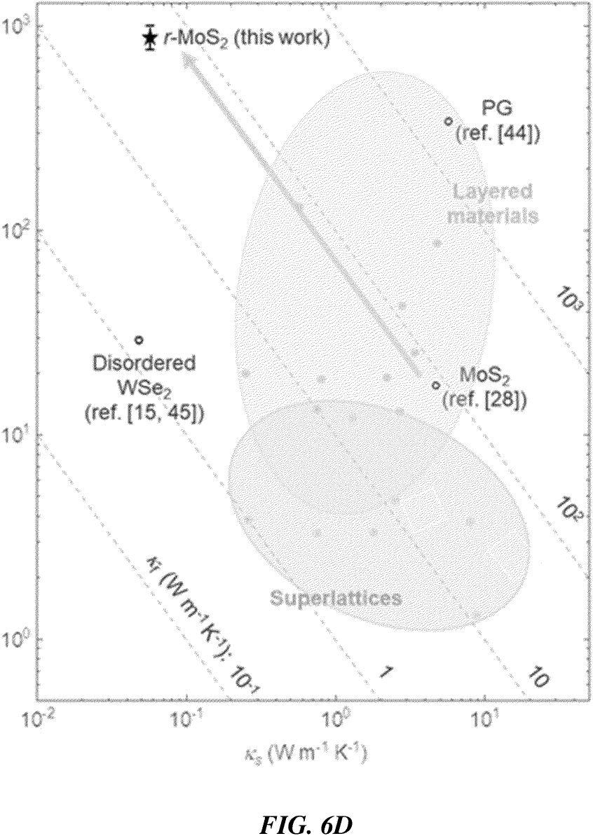

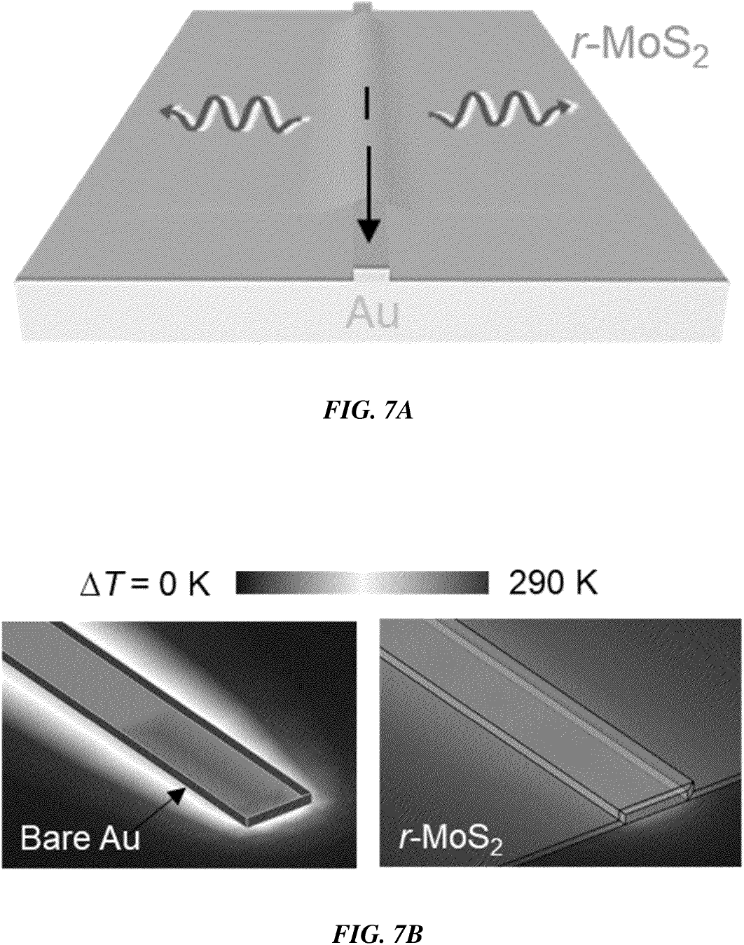

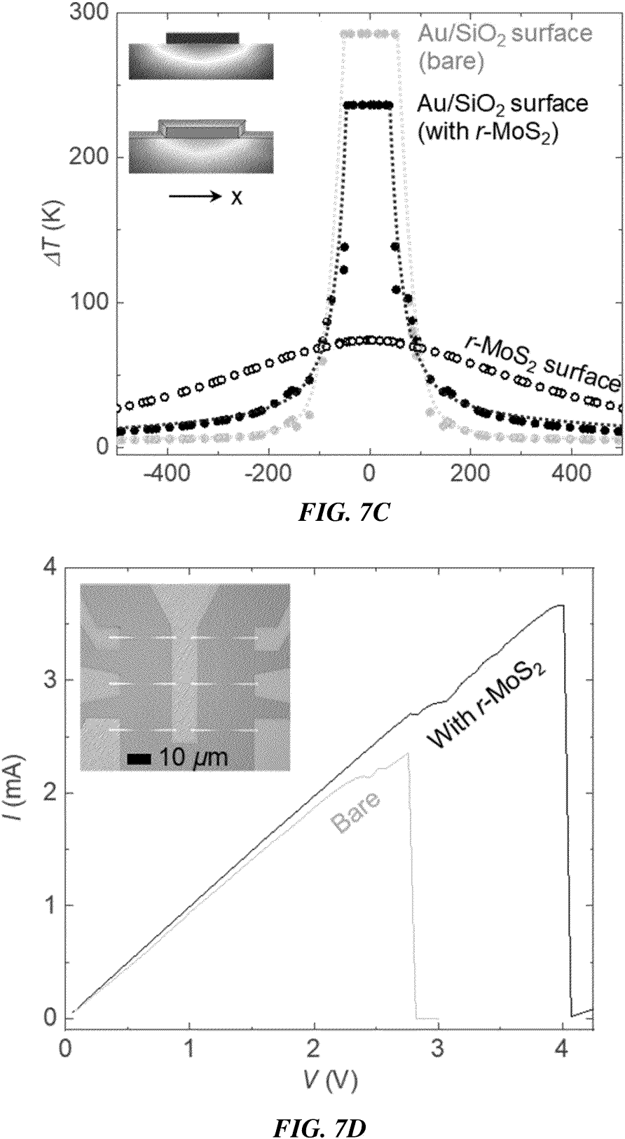

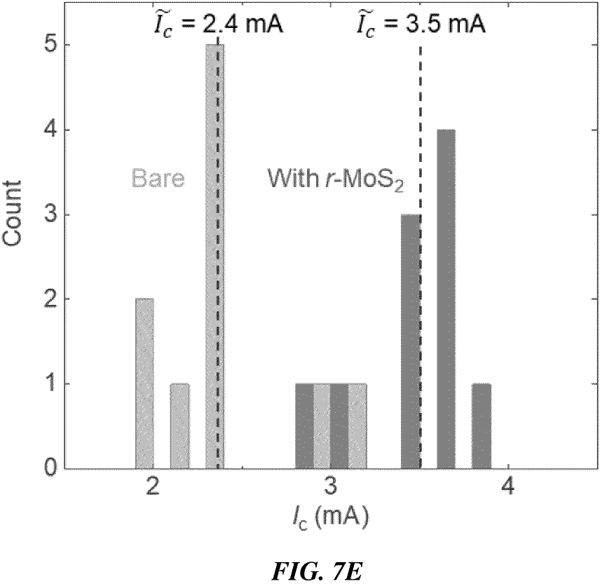

This two-step fabrication approach gives independent control of the in-plane crystallinity via growth and out-of-plane rotation via stacking, an advantage over methods that utilize direct deposition (e.g., molecular beam epitaxy and sputtering). In addition, both the growth and stacking steps are scalable and can produce r-TMD films with the large lateral dimensions that may be useful for real-world applications, as shown by the optical images of N = 1 and N = 10 r-MoS₂ films (~ 1 cm²) in FIG. 4D and as demonstrated later in FIGS. 7A-7E. The large-scale uniformity of these films also enables precise and reproducible measurements of κ⊥ and κ∥. In these experiments, r-MoS₂ or r-WS₂ films with different N (up to 22) are transferred onto a sapphire wafer for the measurements of κ⊥ or suspended over a holey TEM grid (FIG. 6A) for the measurements of κ∥.

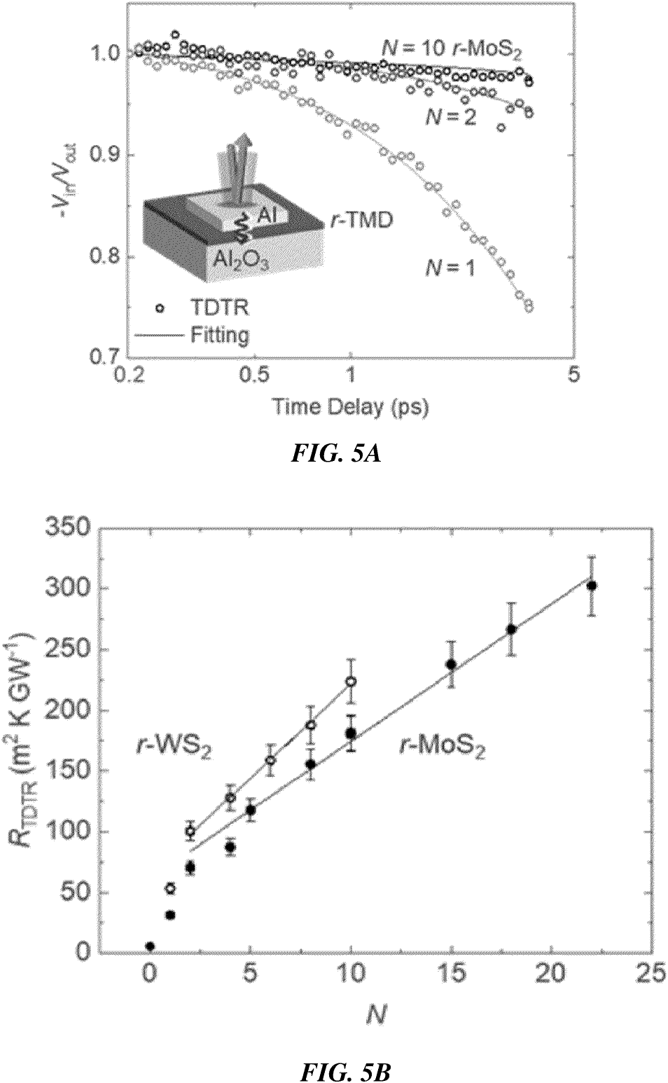

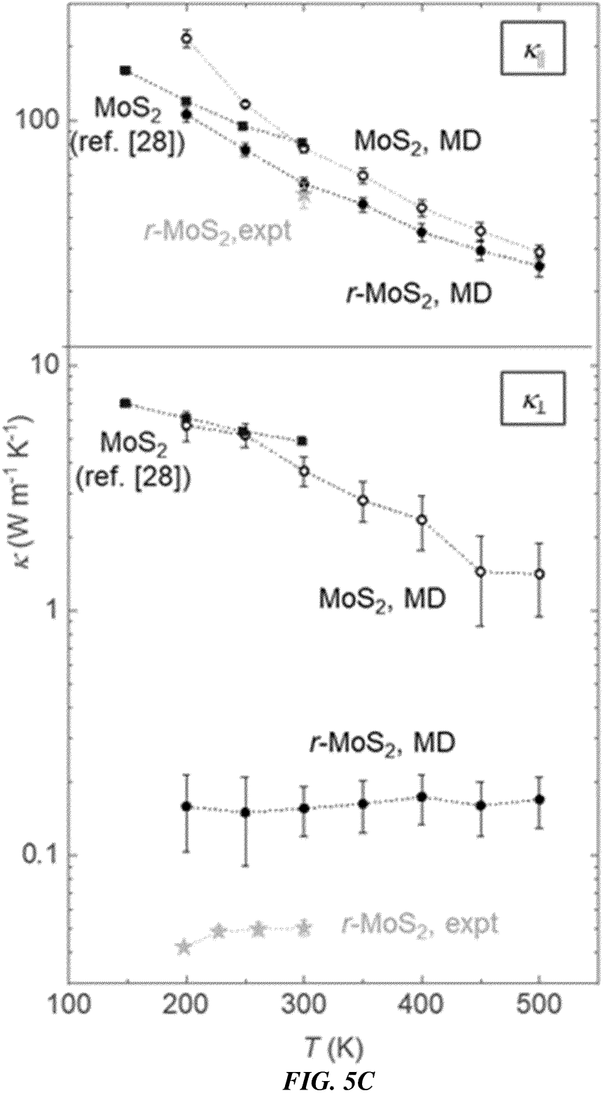

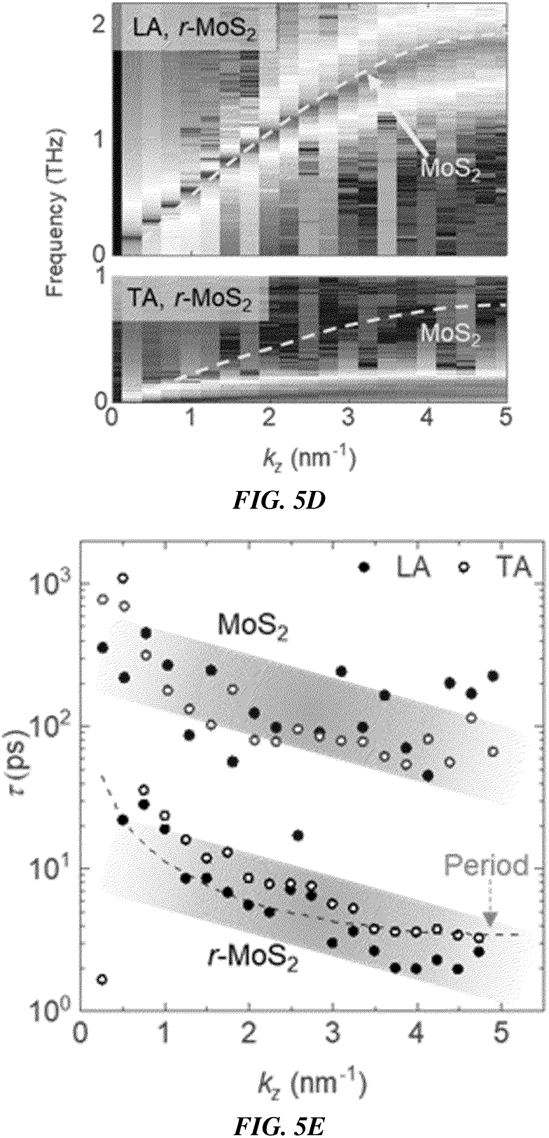

In FIGS. 5A-5E, κ⊥ of r-TMD films is illustrated, which is measured using TDTR (FIG. 5A). For this measurement, an array of square Al pads was deposited (90 µm wide, 90 nm thick) onto an r-TMD film on sapphire. A stream of laser pulses heated the surface of an Al pad (pump) and produced a temperature-sensitive signal (probe; corresponding to -V_{in/}Vₒᵤₜ in FIG. 5A) through the thermoreflectance of Al. Repeating the pump-probe measurements with varying pulse time delays produces a cooling curve corresponding to the heat dissipation from Al. FIG. 5A shows three representative curves measured from r-MoS₂ with N = 1, 2, and 10. The curves flatten with increasing N, suggesting that heat dissipation slows down significantly despite the nanoscale increases in film thickness. Fitting these curves using a heat diffusion model (solid lines, FIG. 5A) enabled the obtaining of RTDTR, the total thermal resistance between the Al transducer layer, and sapphire across the r-TMD film for different N.

FIG. 5B shows R_{TDTR} versus N for r-MoS₂ (N ≤ 22; solid circles) and r-WS₂ (N < 10; open circles) measured under ambient conditions. Two observations were noted. First, R_{TDTR} monotonically increased with N. Second, R_{TDTR} varied linearly with N for N ≥ 2. These observations confirm that the through-plane thermal transport in r-TMD films is diffusive in nature, in contrast to the ballistic transport reported in few-layer single-crystalline MoS₂ without interlayer rotations (as thick as 240 nm). These observations also confirm that a single parameter κ⊥ characterizes the thermal resistance across r-MoS₂ (or r-WS₂) for N ≥ 2 using the equation R_{TDTR} = R₀ + Nd/ κ⊥, whereby Nd is the total film thickness, and R₀ is a constant corresponding to the total interface resistance (r-TMD/Al and r-TMD/sapphire). Therefore, a linear fitting can be applied to the data (N ≥ 2) in FIG. 5B (solid lines) to determine κ⊥ of r-MoS₂ alone, regardless of the quality and chemical nature of the top and bottom interfaces, which can potentially be altered by metal deposition. The measurement for κ⊥ was 57 ± 3 mW m⁻¹ K⁻¹ for r-MoS₂ and κ⊥ was 41 ± 3 mW m⁻¹ K⁻¹ for r-WS₂. These values are similar to the lowest value ever observed in a fully dense solid (disordered nanocrystalline WSe₂) and comparable to the thermal conductivity of ambient air (~ 26 mW m⁻¹ K⁻¹). The measured κ⊥ values are approximately two orders of magnitude smaller than those of single crystalline MoS₂ (2 -5 W m⁻¹ K⁻¹) or WS₂ (~ 3 W m⁻¹ K⁻¹), despite the r-TMD films having the same chemical composition as their bulk counterparts as well as clean interfaces (FIG. 4C). This strongly suggests that the main difference, the interlayer rotation, is the principal cause for the ultralow κ⊥ in these r-TMD films. Furthermore, repeating similar TDTR experiments on r-MoS₂ at different temperatures (T) produces a relatively flat κ⊥(T) curve (stars, FIG. 5C), a behavior different from the decreasing κ⊥ with T seen in bulk MoS₂ (squares, FIG. 5C).

To understand the microscopic mechanisms that give rise to the dramatic reduction in κ⊥, homogeneous non-equilibrium molecular dynamics (HNEMD) simulations were carried out for the model structures of r-MoS₂ and bulk MoS₂. FIG. 5C shows κ∥ and κ⊥ of r-MoS₂ (solid circles) and bulk MoS₂ (empty circles) calculated from MD simulations at different temperatures. The MD simulations reproduce two main effects of interlayer rotations on κ⊥ seen in the TDTR experiments: suppressing κ⊥ and altering its temperature dependence. The calculated value for κ⊥ drops by a factor of more than 20, from 3.7 ± 0.5 W m⁻¹ K⁻¹ in bulk MoS₂ to 0.16 ± 0.04 W m⁻¹ K⁻¹ in r-MoS₂ at 300 K and furthermore does not decrease with T, suggesting a transition away from the phonon-limited thermal transport mechanism observed in bulk MoS₂.

Further analysis of the vibrational spectrum of r-MoS₂ allowed for the break down of the reduction in κ⊥ in terms of the changes to the group velocities (v_{g}) and lifetimes (τ), which, without wishing to be bound by theory, are the two factors that it is believed determine the thermal conductivity according to Boltzmann transport theory. In FIG. 5D, the dispersion of through-plane acoustic modes in r-MoS₂ at 300 K was illustrated, where the v_{g} of the through-plane longitudinal acoustic (LA) mode in r-MoS₂ remains similar to that of bulk MoS₂ (dashed lines). On the other hand, the through-plane transverse acoustic (TA) modes in r-MoS₂ undergo extreme softening with their group velocities practically vanishing, as seen from the flattening of the dispersion curve. A near-zero TA group velocity also implies a loss of resistance with respect to lateral shear. This is consistent with the low-frequency Raman spectra of r-MoS₂ films, which show no measurable shear vibrational peaks within the detection frequency window and previous density-functional theory calculations for twisted bilayer MoS₂. In FIG. 5E, the lifetimes (τ) of both the LA and TA modes in r-MoS₂, which are more than one order of magnitude smaller than in bulk MoS₂. The LA lifetimes are close to the period of the LA mode vibration (dashed line, extracted from FIG. 5D), indicating strongly overdamped behavior. From these results, the median mean free path l̃ = v_{g}τ for the LA modes is estimated to be 2 nm, suggesting that the heat-carrying LA modes are strongly scattered even in r-MoS₂ films with nanoscale thicknesses. This also suggests that because of the low density of grain boundaries (D >>l̃), a larger D is unlikely to significantly affect κ⊥. Overall, the strongly suppressed TA modes, indicating a loss of resistance to lateral shear, and the overdamping of the LA modes as the main heat carriers, lead to extremely inefficient thermal transport along the through-plane direction in r-MoS₂. Along with the nearly temperature independent κ⊥, it is believed this result suggests a glass-like conduction mechanism.

In contrast to κ⊥, κ∥ remains high in the simulations with only a modest reduction compared to the ideal bulk crystal (less than a factor of two at 300 K; FIG. 5C) and exhibits a temperature dependence that is consistent with a phonon-limited transport mechanism. This is indeed what was observed in the Raman thermometry experiments as discussed in FIG. 6. The samples were prepared by suspending r-MoS₂ on holey TEM grids (FIG. 6A). To measure the thermal properties, a focused laser spot (λ, = 532 nm) was focused to the center of the suspended film (hole diameter = 5 µm) and track the shifts in the A_{1g} Raman peak, which is insensitive to lateral strain, at various laser powers at 15 Torr (schematic in FIG. 6B, inset). At this pressure, it was confirmed that all heat is confined to conduction through the film, since repeating the Raman thermometry measurements at a lower pressure (~ 1 mTorr) yielded the same results. The laser power absorbed by the film (P_{abs}) increased its temperature (ΔT) locally, which was measured using the temperature-sensitive Raman peak shift (Δω) following a T vs ω calibration protocol for each sample. This yielded a sensitivity (ldω/dTl) of 0.014 - 0.020 cm⁻¹ K⁻¹. As an example, FIG. 6B shows Raman spectra measured for N = 2, which clearly displayed redshifting of the E_{2g} (left) and A_{1g} (right) peaks with increasing P_{abs}.

Based on similar measurements, Δω vs P_{abs} was plotted for r-MoS₂ with different N (2 - 5) in FIG. 6C. The slope of the linear fit (ld(Δω )/dP_{abs}l), which was inversely proportional to the in-plane thermal conductance of the film, is plotted for each N in the inset to FIG. 6C (solid dots; D ≈ 1 µm). A linear relation was observed, which indicates that κ∥ is well-defined for r-MoS₂ independent of N, similar to the case of κ⊥. Using a simple diffusion model with radial symmetry, a high κ∥ value of 50 ± 6 W m⁻¹ K⁻¹ was calculated. This value is similar to the predictions of the MD simulations (FIG. 5C) and consistent with previous reports of Raman thermometry on single-crystalline monolayer MoS₂ (35 - 84 W m⁻¹ K⁻¹) at room temperature. κ∥ of these r-MoS₂ films was close to the intrinsic phonon-limited value despite the films being made of polycrystalline monolayers. This result was further supported by the additional measurements on continuous r-MoS₂ films with a smaller D ≈ 400 nm (open dots, dashed lines, FIG. 6C inset. The measured value of κ∥ ≈ 44 ± 6 W m⁻¹ K⁻¹ is within the margin of error to that of D ≈ 1 µm films. This suggests that the phonon mean free path is smaller than 400 nm, which is consistent with previous reports. Furthermore, the Raman thermometry measurements of r-MoS₂ conducted at different temperatures show that the in-plane conductance decreases with T. This further confirms the phonon-mediated thermal transport mechanism in-plane, in contrast to the glass-like thermal conduction along the through-plane direction.

Altogether, the thermal measurements and simulations in FIGS. 5A-5E and FIGS. 6A-6D confirm that interlayer rotation in r-TMD films results in highly directional thermal conductivity and a direction-dependent thermal conduction mechanism. It has been seen that the rotation significantly reduces κ⊥ while maintaining high κ∥, leading to an ultrahigh value of ρ. It is estimated ρ ≈ 880 ± 110 at room temperature for the r-MoS₂ films, higher than that of pyrolytic graphite (PG), which is considered to be one of the most anisotropic thermal conductors (ρ ≈ 340). It was also found that the interlayer rotation in r-TMDs introduces disorder only along the through-plane direction, affecting almost exclusively the interplanar force constants, while maintaining the intra-planar force constants and the in-plane periodicity. This gives rise to a behavior that can be described as one-dimensional glass-like conduction with two-dimensional crystalline conduction along different directions, simultaneously realized in a single material.

In FIG. 6D, the result is compared with other previously reported values of p in phonon-based solids. Compared to a bulk MoS₂ crystal (ρ ≈ 20) or disordered layered WSe₂ (ρ ≈ 30), r-MoS₂ has a significantly larger ρ because interlayer rotation reduces only κ⊥ while leaving the high κ∥ relatively unaffected, as denoted by the arrow parallel to the equi-κ_{F} lines. This also suggests that ρ can be made even larger by starting with the monolayers of a layered vdW material with a higher κ∥ value such as graphene. A similar 100-fold reduction in κ⊥ due to interlayer rotation in few-layer graphene could produce ρ > 10⁴.

In FIG. 7, the extreme anisotropy of the r-MoS₂ films is shown and can lead to excellent heat dissipation in-plane from a heat source and drastic thermal insulation in the through-plane direction. Using the COMSOL software, thermal finite-element simulations were performed of a 10 nm thick r-MoS₂ film draped over a 15 nm (height) × 100 nm (width) × 10 µm (length) Au electrode on a 50 nm SiO₂/Si substrate (FIG. 7A). The simulation results showed that for a fixed power of 8 mW supplied to the Au electrode (near thermal breakdown), the temperature rise ΔT of the Au electrode covered by r-MoS₂ was 50 K lower than that of the bare electrode, thereby demonstrating the film’s effectiveness at spreading heat due to its excellent κ∥ (FIGS. 7B, 7C). Interestingly, the extreme thermal anisotropy of the r-MoS₂ films provided thermal insulation in the through-plane direction, with much lower MoS₂-surface ΔT values that were only a third of the value of the bare Au electrode, sustaining a ∼ 160 K temperature gradient across a mere 10 nm thick film. While single crystal MoS₂ displays similar properties, the insulation effect is stronger in r-MoS₂. This implies that heat is efficiently directed from the hot Au electrode laterally through r-MoS₂ than to the underlying substrate but not to the surface of r-MoS₂. This makes the surface of the entire device significantly cooler, which could further protect any subsequent device layer defined on this surface from overheating.

These experiments confirmed these simulation results, as shown in FIGS. 7D and 7E. For this, nanoscale Au electrodes were fabricated with the same geometry and substrate as in the simulation (image shown in FIG. 7D, inset) and transfer N = 16 r-MoS₂ (~ 10 nm thick) using the vacuum stacking process. Both bare and coated Au electrodes show similar resistance at low currents. At higher currents, current-induced Joule heating leads to the thermally activated electromigration process which caused the electrodes to fail. FIG. 7D compares representative I-V curves measured from a bare and coated Au electrode, which shows that the Au electrode with r-MoS₂ can carry a larger current without breaking. The histogram of critical current I_{c} (maximum current a Au electrode sustains for at least 20 s) measured from 20 electrodes (10 bare and 10 with r-MoS₂) revealed a ∼ 50% increase in the median I_{c} values, measuring 3.5 mA with the presence of r-MoS₂ and 2.4 mA without (FIG. 7E), which translates to more than doubling of the maximum electrical power transmitted by the Au electrodes. These results demonstrated that the r-MoS₂ film’s ability to efficiently dissipate Joule heat and keep the electrodes cool, as the simulation predicted. As the electromigration process is dominated by the temperature, the observed increase of I_{c} and maximum power before breaking is in good agreement with the simulation in FIG. 7C. Furthermore, it is noted that the r-MoS₂ film can be integrated with the Au electrodes using mild conditions that do not affect their electrical properties. In contrast, direct deposition of an ultrathin inorganic film such as SiNₓ which has a comparable κ to κ∥ of r-MoS₂, negatively affects the performance of the Au electrodes, increasing their resistance by over twofold and decreasing I_{c} by half.

It is expected that interlayer rotation will be an effective and generalizable way to reduce κ⊥ and potentially engineer anisotropic thermal properties in a variety of layered materials that can be synthesized in large scale, including graphene and hexagonal boron nitride. The results call for a systematic study of the exact relation between κ⊥ and rotation angle, which can be conducted with samples produced by angle-controlled stacking of large-scale vdW monolayers with known lattice orientations. Such studies could reveal unexpected relationships between the rotation angle and phonon transport, analogous to the studies of electrical transport in twisted bilayer graphene. Interlayer rotations may be combined with other parameters (such as pressure or interlayer spacing) to further tune the thermal transport in vdW layered materials. Such materials can have widespread practical use for directed thermal management in densifying electronics and in wearable electronics, where safety and user physiological comfort requires excellent thermal insulation. While this work has only focused on characterizing r-TMD films made with the same monolayer building blocks, the approach can be used to produce engineered vdW superlattices and heterostructures with highly tunable ρ, allowing for the customization of thermal properties through which heat can be routed along specific directions as desired with an unprecedented level of spatial control.

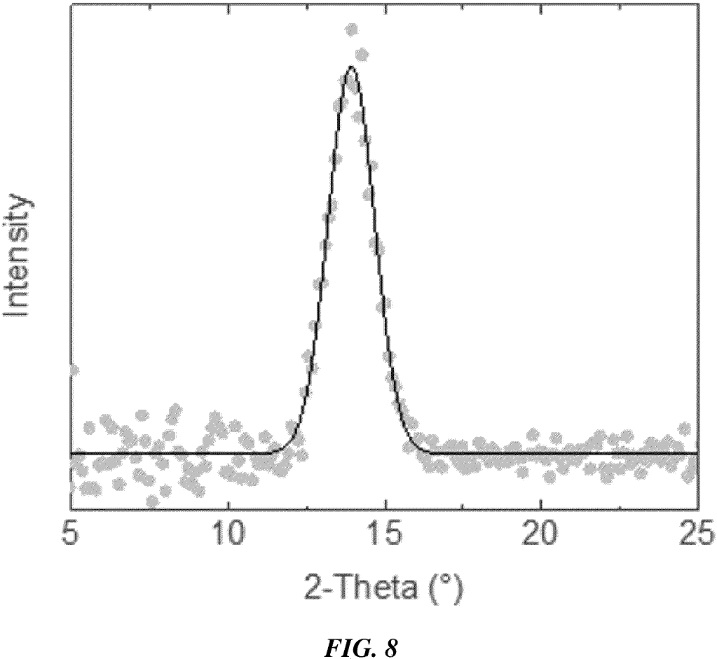

FIG. 8 shows GIWAXS data of N = 10 r-MoS₂, where the peak position corresponds to a 2-Theta value of 14 °, which translates to an interlayer spacing of 6.4 Å (scattering direction).

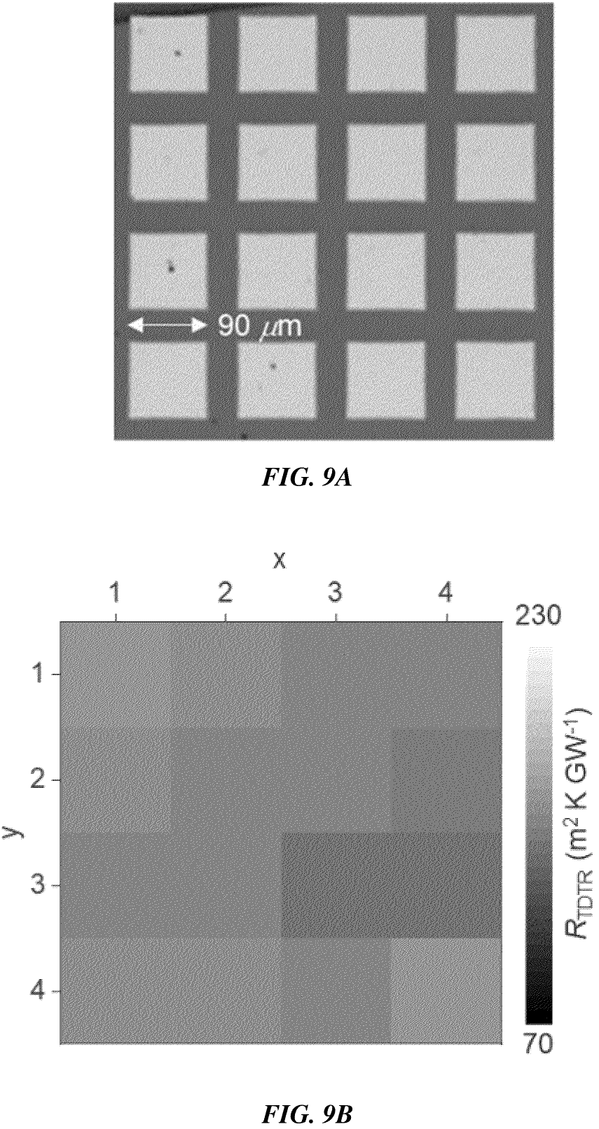

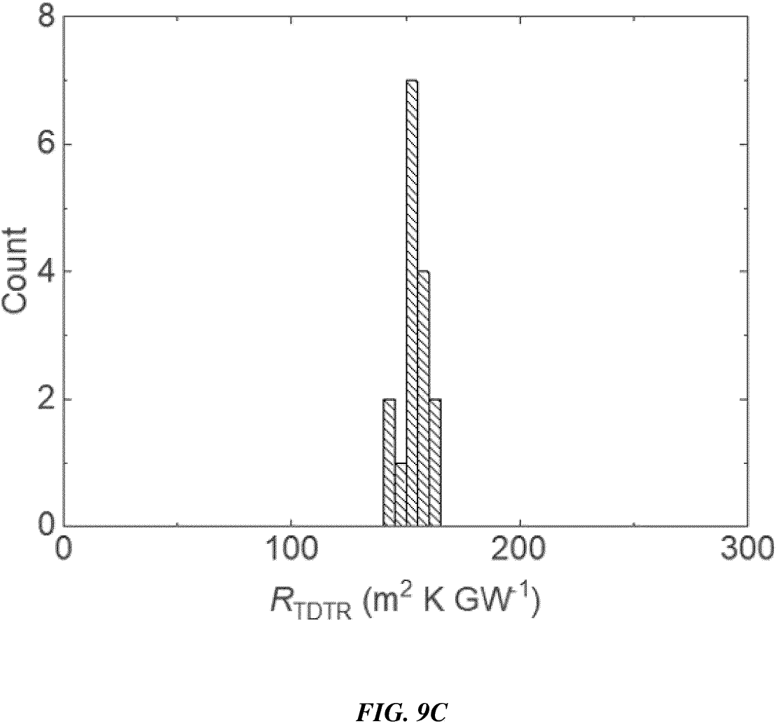

FIGS. 9A-9C show TDTR array measurements of N = 10 r-MoS₂, according to some embodiments. FIG. 9A shows a microscope image of a N = 10 r-MoS₂ film coated with a square grid of Al pads. FIG. 9B shows a 4 ×4 TDTR map of R_{TDTR} of a N = 10 r-MoS₂ film. FIG. 9C shows a histogram of R_{TDTR} array measurements.

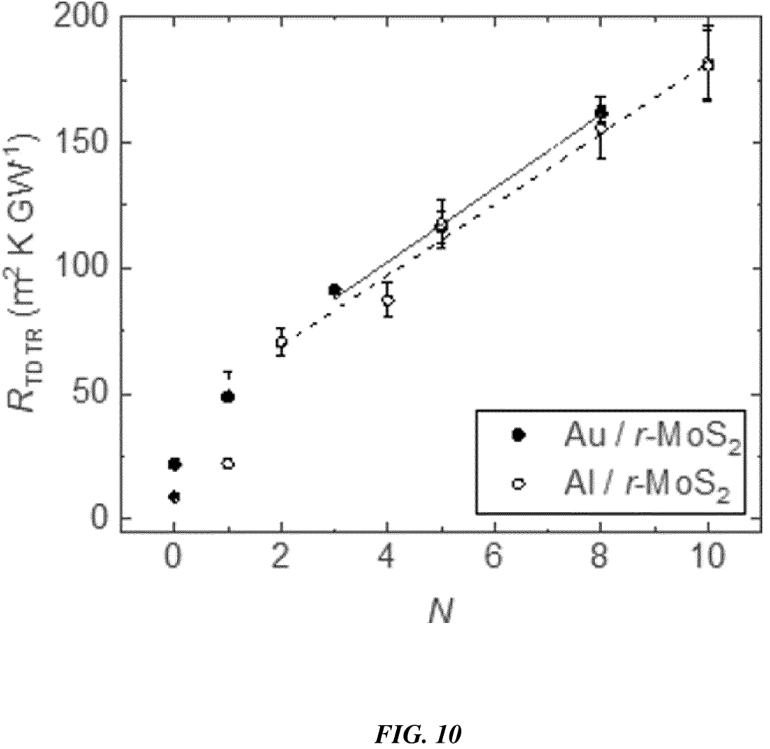

FIG. 10 shows TDTR measurements of N ≤ 10 r-TMD films coated with Au or Al.

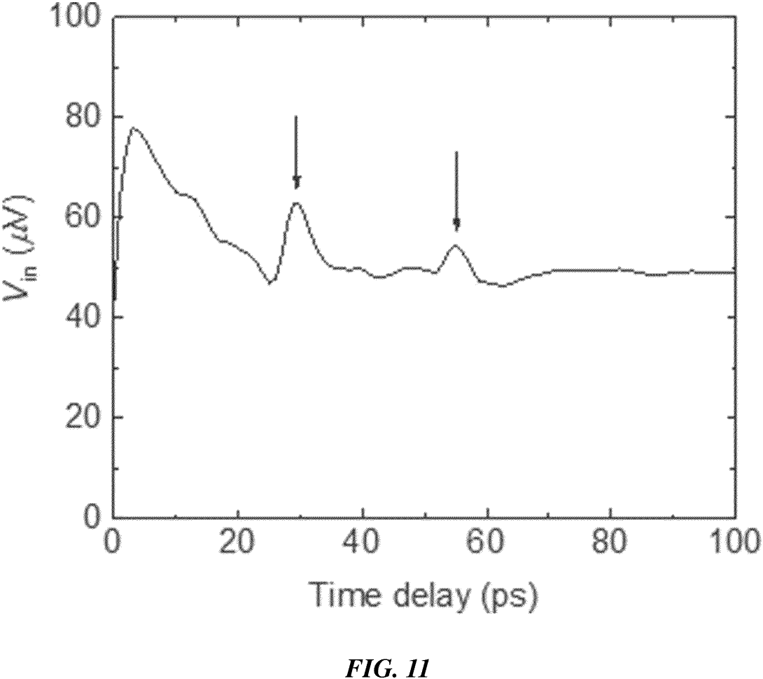

FIG. 11 shows picosecond acoustics of a MoS₂ monolayer on thick sapphire substrate, coated with an Al transducer layer, in which the y-axis Vᵢₙ is an in-phase signal of a lock-in amplifier, the red arrows indicate acoustic waves reflected at a Al/MoS₂ interface, and the speed of sound of Al as 6.42 nm ps⁻¹ is used to calculate the thickness of Al (about 93 nm).

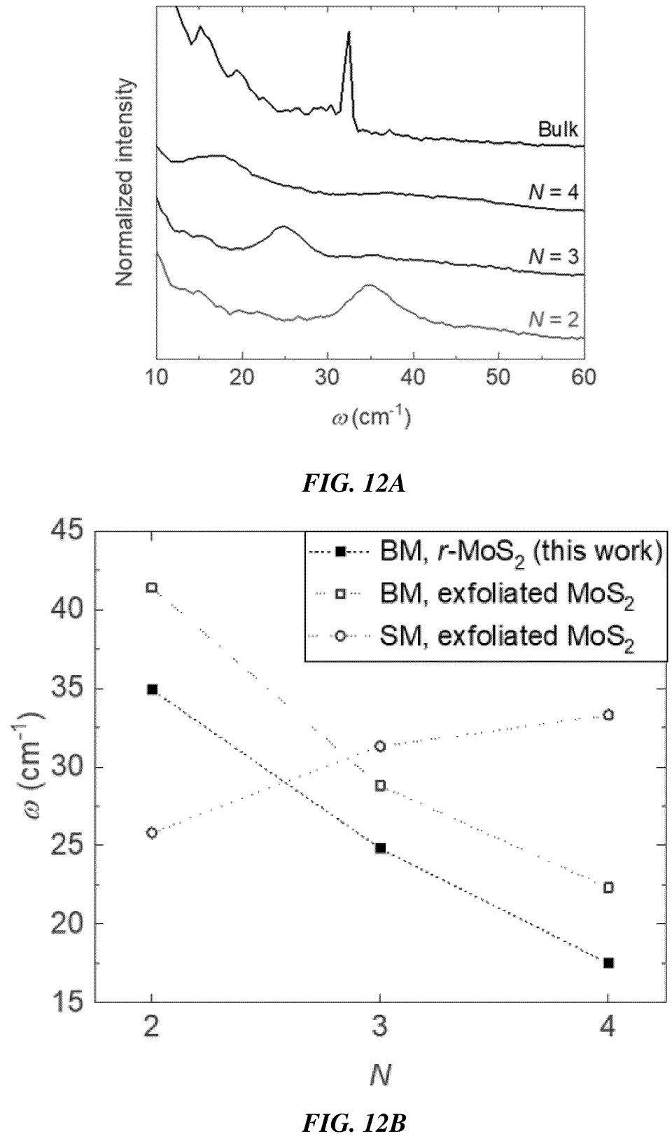

FIGS. 12A-12B show low frequency Raman modes of r-MoS₂. FIG. 12A shows Raman spectra reflecting the breathing modes (BM) of r-MoS₂ and a shear mode (SM) for bulk MoS₂. FIG. 12B shows a low frequency Raman peak positions of r-MoS₂ and exfoliated MoS₂, in which filled squares indicate BM peak positions of r-MoS₂, open squares indicate BM peak positions of exfoliated MoS₂, and open circles indicate SM peak positions of exfoliated MoS₂.

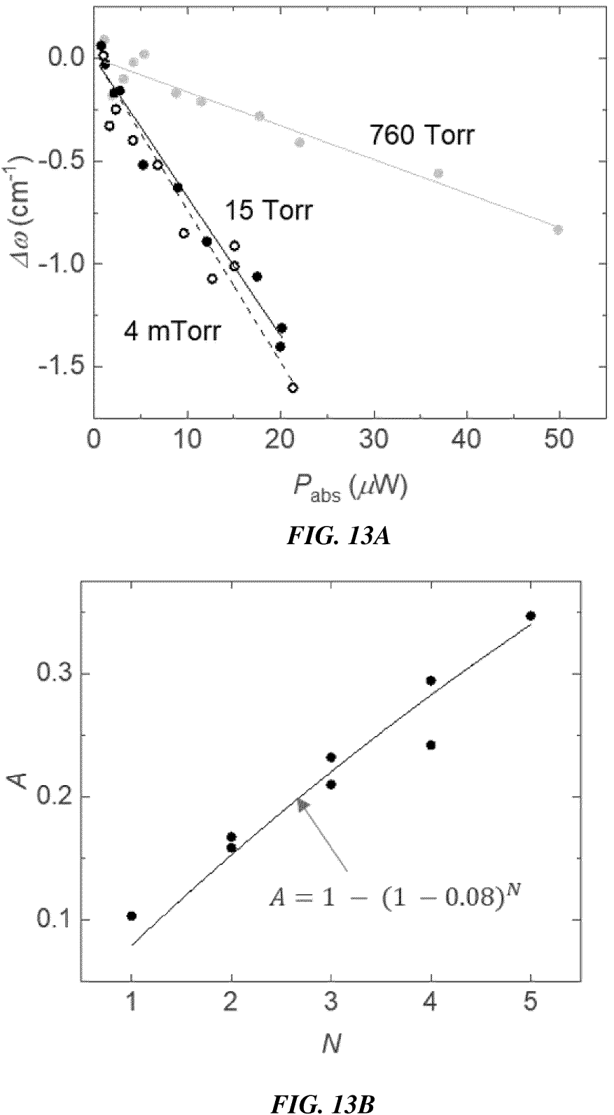

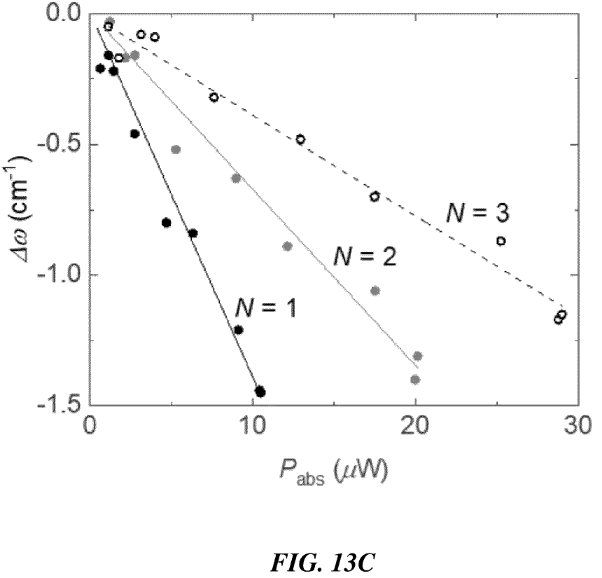

FIGS. 13A-13C show Raman thermometry on r-MoS₂ films. FIG. 13A shows Δω-P_{abs} curves of representative N = 2 r-MoS₂ films at different pressures, in which P_{abs} values along the x-axis are normalized to account for slight differences in beam spot sizes (Δr = 20%). FIG. 13B shows optical absorption of suspended r-MoS₂ films, which follows the trend A = 1 - (1 - A₀)^{N}, whereby A₀ comprises a monolayer absorptance, which was determined from the fit as A₀ = 0.08 ± 0.003. FIG. 13C shows A_{1g} peak shifts vs power absorbed by r-MoS₂ films made up of D = 400 nm (grain size) monolayers.

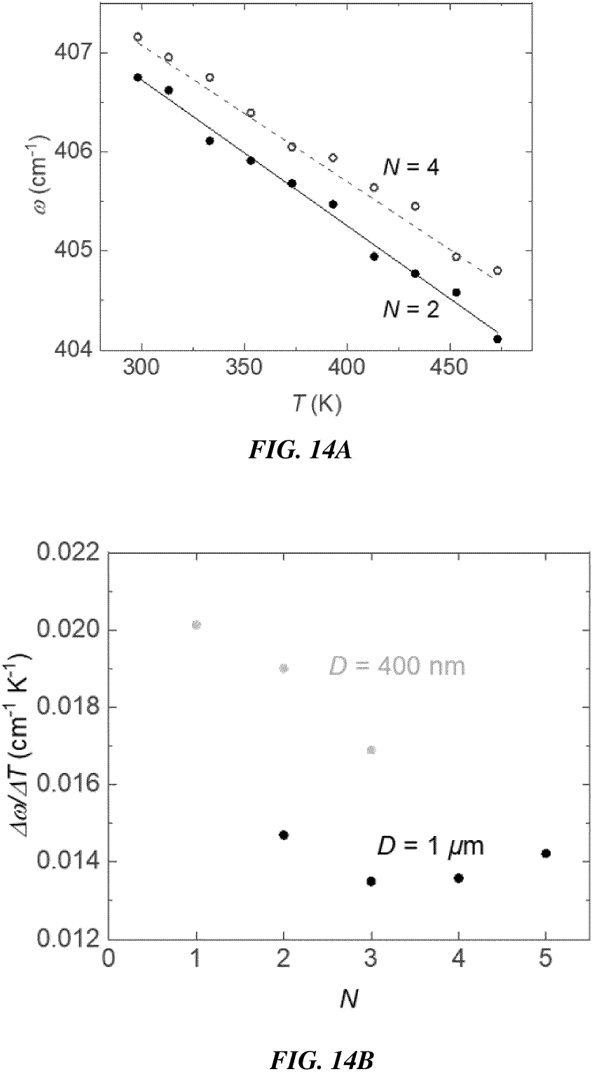

FIGS. 14A-14B show temperature coefficients of r-MoS₂ for Raman thermometry. FIG. 14A shows ω-T calibration measurements of suspended r-MoS₂ films (D = 1 µm), with N = 2 and N = 4 data as representative curves. FIG. 14B shows ω-T slopes vs layer number for all films.

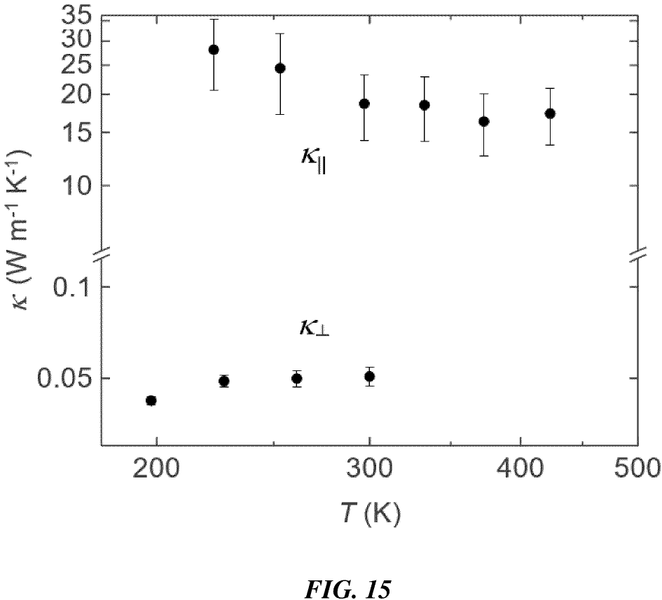

FIG. 15 shows κ(T) of r-MoS₂, with κ∥ measured using Raman thermometry of N = 4 r-MoS₂, and κ⊥ measured via TDTR as reported in FIG. 5C.

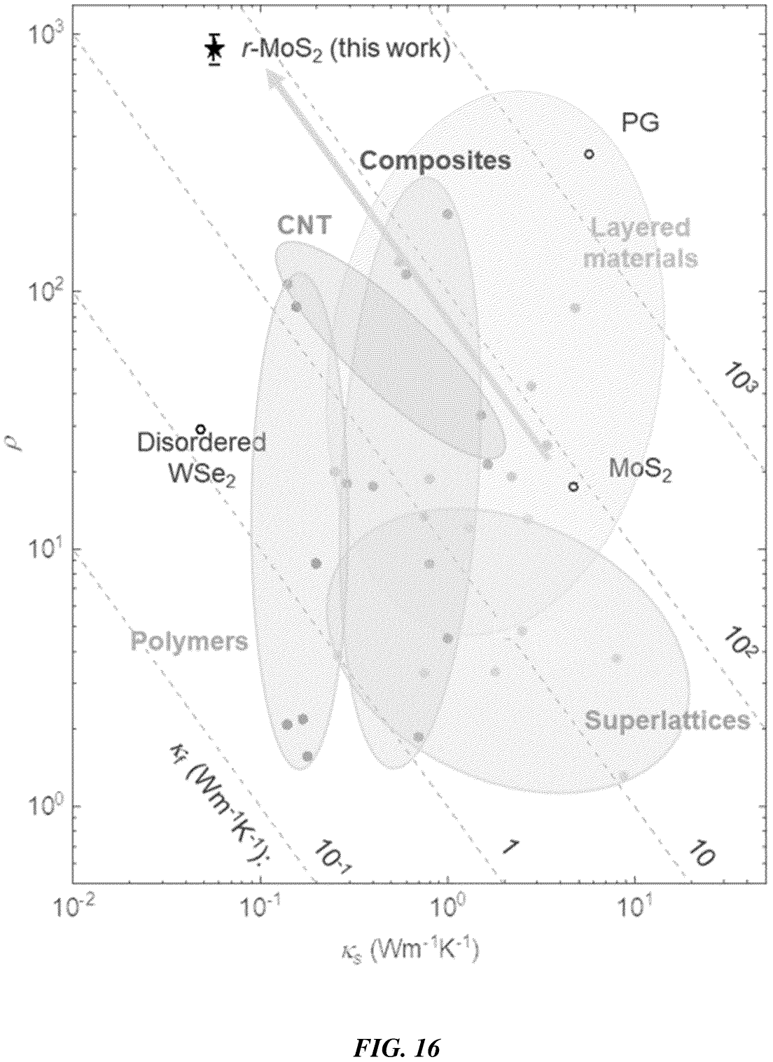

FIG. 16 shows a catalogue of experimentally-measured anisotropy ratios at room temperature vs slow-axis thermal conductivity (κ_{S}) of thermally anisotropic materials from literature, by category.

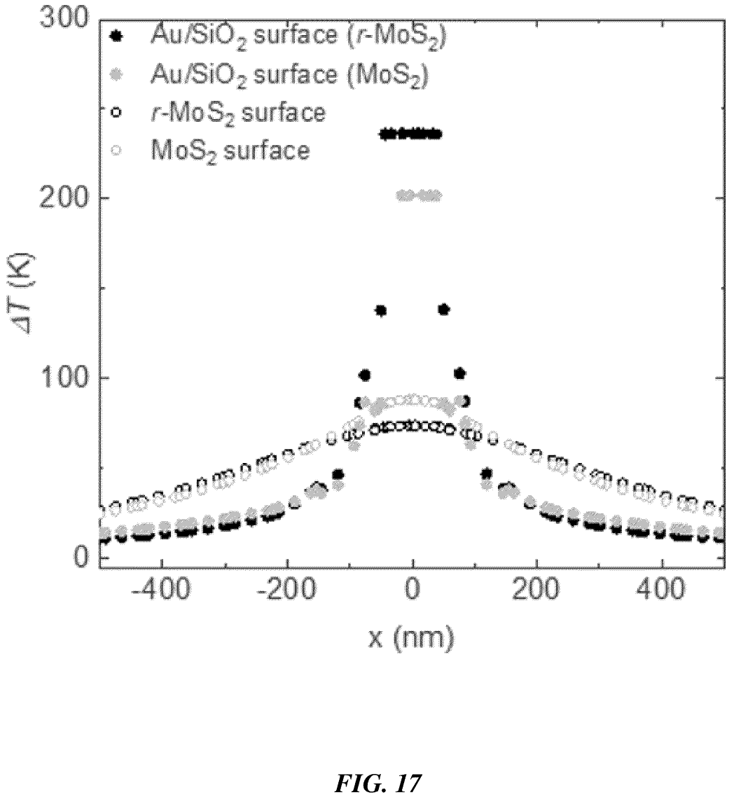

FIG. 17 shows finite element simulations of the linear temperature profiles of Au electrodes covered with MoS₂ and r-MoS₂.

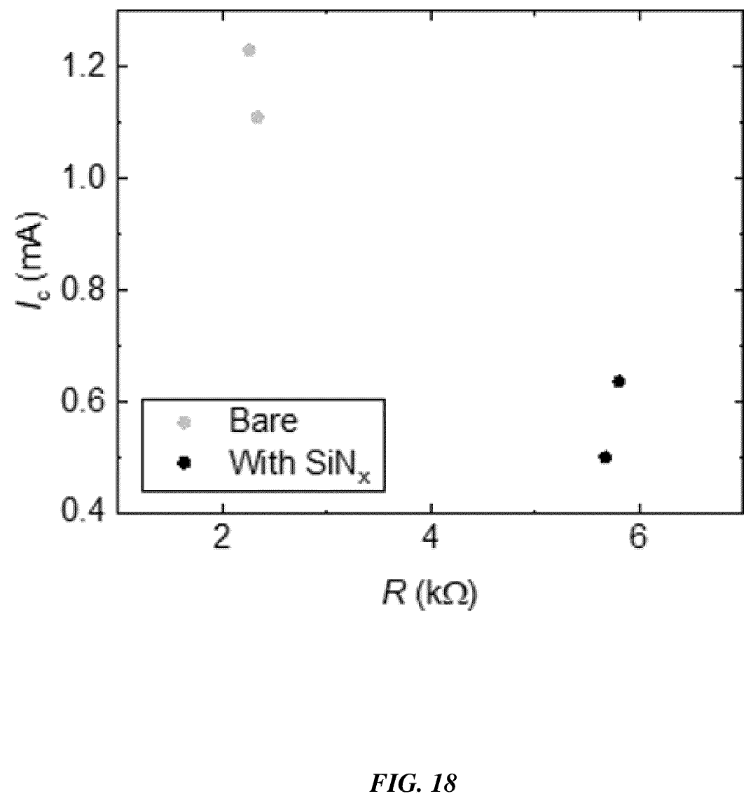

FIG. 18 shows SiNₓ as heat spreaders for Au electrodes, where electrical properties of 10 nm thick, 100 nm wide, and 10 µm long Au electrodes before and after 16 nm SiNₓ film deposition onto the electrodes using plasma-enhanced chemical vapor deposition were measured.

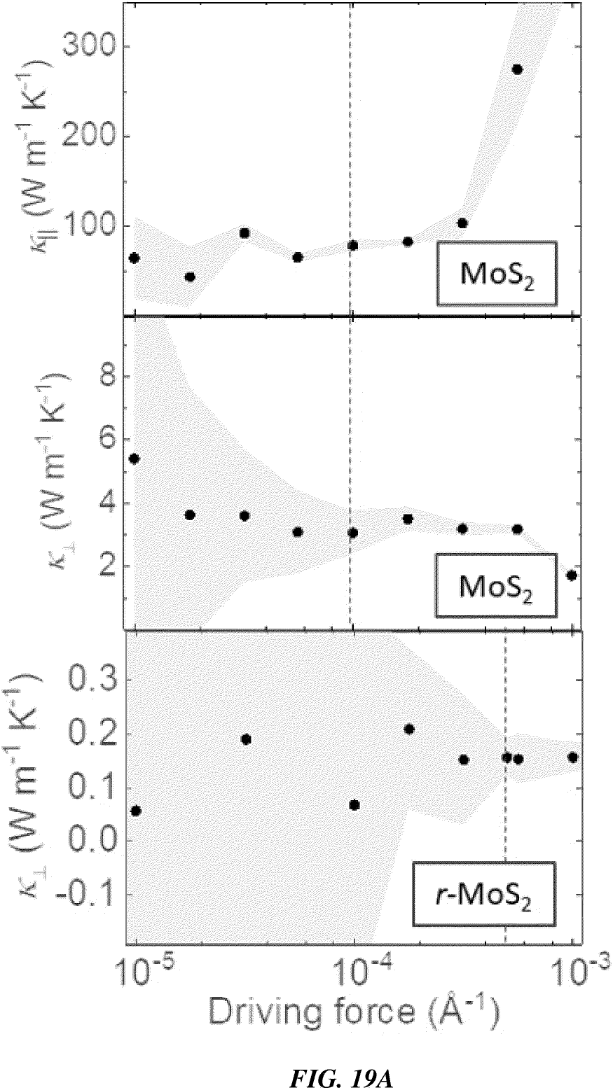

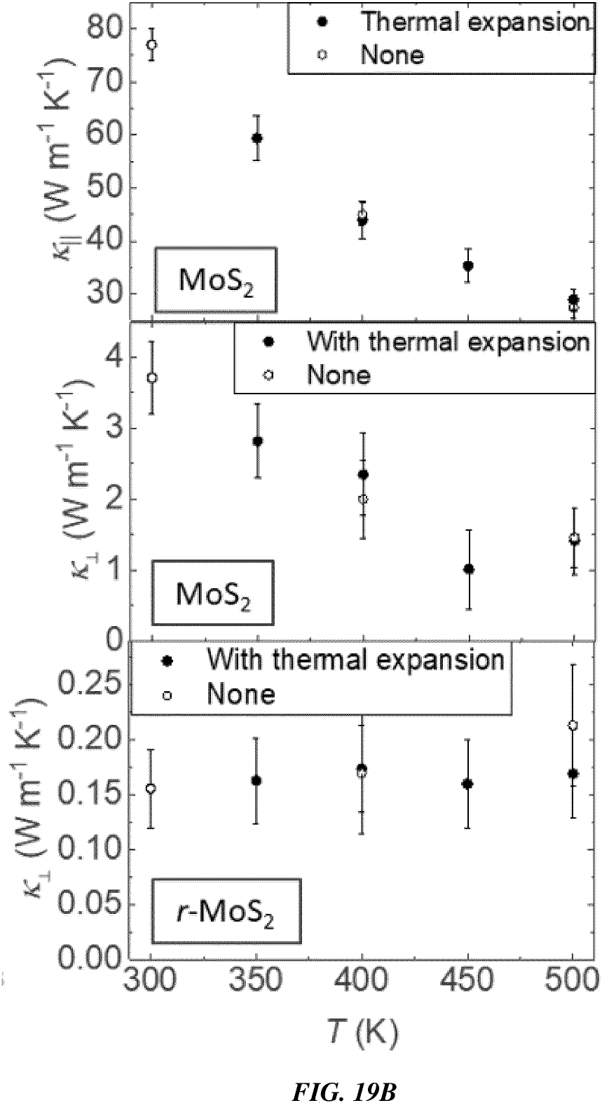

FIGS. 19A-B show optimization of the MD simulations for κ calculations. FIG. 19A shows optimization of the driving force of the system, whereby the grey zone denotes the error. FIG. 19B shows an effect of thermal expansion on κ.

While several embodiments of the present disclosure have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present disclosure. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present disclosure is/are used. Those skilled in the art will recognize or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present disclosure is directed to each individual feature, system, article, material, and/or method described herein. In addition, any combination of two or more such features, systems, articles, materials, and/or methods, if such features, systems, articles, materials, and/or methods are not mutually inconsistent, is included within the scope of the present disclosure.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

Some embodiments may be embodied as a method, of which various examples have been described. The acts performed as part of the methods may be ordered in any suitable way. Accordingly, embodiments may be constructed in which acts are performed in an order different than illustrated, which may include different (e.g., more or less) acts than those that are described, and/or that may involve performing some acts simultaneously, even though the acts are shown as being performed sequentially in the embodiments specifically described above.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

In the claims, as well as in the specification above, all transitional phrases such as “comprising,” “including,” “carrying,” “having,” “containing,” “involving,” “holding,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A device, comprising:
a heat source;
a substrate; and
a multi-layer domain between the heat source and the substrate, the multi-layer domain having a first thermal conductivity in a lateral dimension and a second thermal conductivity in a thickness dimension;
wherein the first thermal conductivity is at least 10 times greater than the second thermal conductivity.

2. The device of claim 1, wherein the multi-layer domain comprises at least two thin film layers.

3. The device of claim 1, wherein the multi-layer domain comprises at least two two-dimensional material layers.

4. The device of claim 1, wherein the multi-layer domain comprises a layer comprising a transition metal dichalcogenide, graphene, or hexagonal boronitride.

5. The device of claim 1, wherein the heat source comprises an electronic circuit element.

6. The device of claim 5, wherein the electronic circuit element comprises a transistor, a resistor, a capacitor, or an electrode.

7. The device of claim 1wherein the heat source comprises a microprocessor.

8. The device of claim 1, wherein the heat source comprises an electrochemical cell.

9. The device of claim 1, wherein the multi-layer domain comprises a plurality of layers of the same chemical composition.

10. The device of claim 1,wherein the multi-layer domain comprises a plurality of layers having different chemical compositions.

11. The device of claim 1, wherein the multi-layer domain comprises at least one single crystalline layer.

12. The device of claim 1, wherein the multi-layer domain comprises at least one polycrystalline layer.

13. The device of claim 1, wherein the first thermal conductivity is or at least 500 times greater than the second thermal conductivity.

14. The device of claim 1, wherein the first thermal conductivity is less than or equal to 1 x10¹⁵ times, greater than the second thermal conductivity.

15. An article, comprising:
a multi-layer domain between the heat source and the substrate, the multi-layer domain having a first thermal conductivity in a lateral dimension and a second thermal conductivity in a thickness dimension;
wherein the first thermal conductivity is at least 10 times greater than the second thermal conductivity.

16. The article of claim 15, wherein the multi-layer domain comprises at least two thin film layers.

17. The article of claim 15,wherein the multi-layer domain comprises at least two two-dimensional material layers.

18. The article of claim 15, wherein the multi-layer domain comprises a layer comprising a transition metal dichalcogenide, graphene, or hexagonal boronitride.

19. The article of claim 15, wherein the multi-layer domain comprises a plurality of layers of the same chemical composition.

20. The article of claim 15, wherein the multi-layer domain comprises a plurality of layers having different chemical compositions.

21. The article of claim 15, wherein the multi-layer domain comprises at least one single crystalline layer.

22. The article of claim 15, wherein the multi-layer domain comprises at least one polycrystalline layer.

23. The article of claim 15, wherein the first thermal conductivity is at least 500 times greater than the second thermal conductivity.

24. The article of claim 15, wherein the first thermal conductivity is less than or equal to 1 x10¹⁵ times, greater than the second thermal conductivity.

25. The article of claim 15, wherein the multi-layer domain is in thermal communication with a heat source such that heat from the heat source is dissipated by the multi-layer domain.
